(19) United States
(12) Patent Application Publication
(10) Pub. No.: US 2026/0214897 A1
(43) Pub. Date: Jul. 23, 2026

(54) SEMICONDUCTOR DEVICE AND ELECTRONIC SYSTEM INCLUDING THE SAME

(71) Applicant: Samsung Electronics Co., Ltd., Suwon-si (KR)

(72) Inventor: Joo Nam Kim, Suwon-si (KR)

(21) Appl. No.: 19/303,810

(22) Filed: Aug. 19, 2025

(30) Foreign Application Priority Data
Jan. 23, 2025 (KR) 10-2025-0010360

(51) Int. Cl. H10B 43/27; H01L 23/00; H01L 25/065; H01L 25/18; H10B 41/10; H10B 41/27; H10B 41/35; H10B 43/10; H10B 43/35; H10B 80/00

(52) U.S. Cl. CPC H10B 43/27; H10B 41/10; H10B 41/27; H10B 41/35; H10B 43/10; H10B 43/35; H10B 80/00; H10W 90/00; H10W 90/792

(57) ABSTRACT

A semiconductor device includes a substrate including: a first cell array region, first to third connection regions, and a second cell array region; a lower stack including lower insulating layers and lower gate electrodes alternately stacked; an upper stack including upper insulating layers and upper gate electrodes, on the lower stack and are alternately stacked; a first vertical channel structure at the first cell array region that penetrates the lower and upper stacks; a second vertical channel structure at the second cell array region that penetrates the lower and upper stacks; and gate contacts at the first to third connection regions. The gate contacts include upper gate contacts that penetrate the upper stack and connected to the upper gate electrodes, on the second connection region, and lower gate contacts that penetrate the lower stack and connected to the lower gate electrodes, on the first and third connection regions.

### CROSS-REFERENCE TO RELATED APPLICATION

This U.S. non-provisional patent application claims priority under 35 U.S.C. § 119 to Korean Patent Application No. 10-2025-0010360, filed on Jan. 23, 2025, in the Korean Intellectual Property Office, the entire contents of which are hereby incorporated by reference.

### BACKGROUND

Due to their small-sized, multifunctional, and/or low-cost characteristics, semiconductor devices are being esteemed as important elements in the electronics industry. The semiconductor devices may be classified into a semiconductor memory device for storing data, a semiconductor logic device for processing data, and a hybrid semiconductor device including both of memory and logic elements.

### SUMMARY

With the trend of high speed and low power consumption of electronic devices, semiconductor devices in the electronic devices may necessitate high operating speeds and/or low operating voltages, and it may be desired to increase an integration density of the semiconductor device. However, as the integration density of the semiconductor device increases, the semiconductor device may suffer from deteriorated electrical characteristics and low production yield. Accordingly, it may be desired to improve the electrical characteristics and production yield of the semiconductor device.

Implementations of present disclosure provide a semiconductor device with improved electrical and reliability characteristics and an electronic system including the same.

An aspect of the present disclosure provides a semiconductor device including a substrate including a first cell array region, first to third connection regions, and a second cell array region, which are sequentially arranged in a first direction, a lower stack including lower insulating layers and lower gate electrodes, which are disposed on the substrate and are alternately stacked on top of another, an upper stack including upper insulating layers and upper gate electrodes, which are disposed on the lower stack and are alternately stacked on top of another, a first vertical channel structure provided on the first cell array region to penetrate the lower and upper stacks, a second vertical channel structure provided on the second cell array region to penetrate the lower and upper stacks, and gate contacts provided on the first to third connection regions and arranged in the first direction. The gate contacts may include upper gate contacts provided to penetrate at least portion of the upper stack and connected to the upper gate electrodes, on the second connection region, and lower gate contacts provided to penetrate at least portion of the lower stack and connected to the lower gate electrodes, on the first and third connection regions.

Another aspect of the present disclosure provides a semiconductor device including a substrate including a first cell array region, first to third connection regions, and a second cell array region, which are sequentially arranged in a first direction, first to third stacks sequentially disposed on the substrate, and each of the first to third stacks including insulating layers and gate electrodes alternately stacked on top of another, a first vertical channel structure disposed on the first cell array region to penetrate the first to third stacks, a second vertical channel structure disposed on the second cell array region to penetrate the first to third stacks, and gate contacts sequentially arranged in the first direction, on the first to third connection regions. The gate contacts may include first outer gate contacts provided to penetrate at least portion of the second stack and connected to the gate electrodes of the second stack, on the first connection region, inner gate contacts provided to penetrate at least portion of the first stack and connected to the gate electrodes of the first stack, on the second connection region, and second outer gate contacts provided to penetrate at least portion of the third stack and connected to the gate electrodes of the third stack, on the third connection region.

An aspect of the present disclosure provides an electronic system including a main substrate, a semiconductor device on the main substrate, and a controller disposed on the main substrate and electrically connected to the semiconductor device. The semiconductor device may include a substrate including a first cell array region, first to third connection regions, and a second cell array region, which are sequentially arranged in a first direction, a lower stack including lower insulating layers and lower gate electrodes, which are disposed on the substrate and are alternately stacked on top of another, an upper stack including upper insulating layers and upper gate electrodes, which are disposed on the lower stack and are alternately stacked on top of another, a first vertical channel structure provided on the first cell array region to penetrate the lower and upper stacks, a second vertical channel structure provided on the second cell array region to penetrate the lower and upper stacks, and gate contacts provided on the first to third connection regions and arranged in the first direction. The gate contacts may include upper gate contacts provided on the second connection region to penetrate at least portion of the upper stack and connected to the upper gate electrodes, and lower gate contacts provided on the first and third connection regions to penetrate at least portion of the lower stack and connected to the lower gate electrodes.

An aspect of the present disclosure provides a method of fabricating a semiconductor device. The method includes providing a substrate including a first cell array region, first to third connection regions, and a second cell array region, which are sequentially arranged in a first direction; sequentially forming a lower mold structure including lower sacrificial layers and an upper mold structure including upper sacrificial layers on the substrate; forming vertical channel structures on the first and second cell array regions to penetrate the upper and lower mold structures; forming first sacrificial patterns connected to the upper sacrificial layers, on the second connection region; forming second sacrificial patterns connected to the lower sacrificial layers, on the first and third connection regions; etching the upper and lower sacrificial layers to form upper and lower gate electrodes; etching the first sacrificial patterns to form upper gate contacts connected to the upper gate electrodes; and etching the second sacrificial patterns to form lower gate contacts connected to the lower gate electrodes.

In some implementations, the forming of the upper gate contacts may include forming a first upper gate contact connected to a first upper gate electrode, which is the topmost one of the upper gate contacts.

In some implementations, the first upper gate electrode may be formed to have a higher resistance than that of each of the lower gate electrodes.

### BRIEF DESCRIPTION OF THE DRAWINGS

FIG. 1 is a schematic diagram illustrating an example of an electronic system including a semiconductor device.

FIG. 2 is a perspective view schematically illustrating an example of an electronic system including a semiconductor device.

FIGS. 3 and 4 are sectional views schematically illustrating an example of semiconductor packages.

FIG. 5 is a plan view illustrating an example of a semiconductor device.

FIG. 6 is a sectional view taken along a line A-A′ of FIG. 5.

FIG. 7A is an enlarged view illustrating a portion ‘P1’ of FIG. 6.

FIG. 7B is an enlarged view illustrating a portion ‘P2’ of FIG. 6.

FIGS. 8A and 8B are enlarged sectional views illustrating an example of a semiconductor device.

FIG. 9A is a sectional view illustrating an example of a semiconductor device.

FIG. 9B is an enlarged view illustrating a portion ‘P3’ of FIG. 9A.

FIG. 10 is a plan view illustrating an example of a semiconductor device.

FIG. 11 is a sectional view taken along a line B-B′ of FIG. 10.

FIGS. 12 to 24 are diagrams illustrating an example method of fabricating a semiconductor device.

### DETAILED DESCRIPTION

Example implementations will now be described more fully with reference to the accompanying drawings, in which example implementations are shown. It will be understood that, although the terms “first”, “second”, etc. may be used herein to describe various elements, components, regions, layers and/or sections, these elements, components, regions, layers, and/or sections should not be limited by these terms.

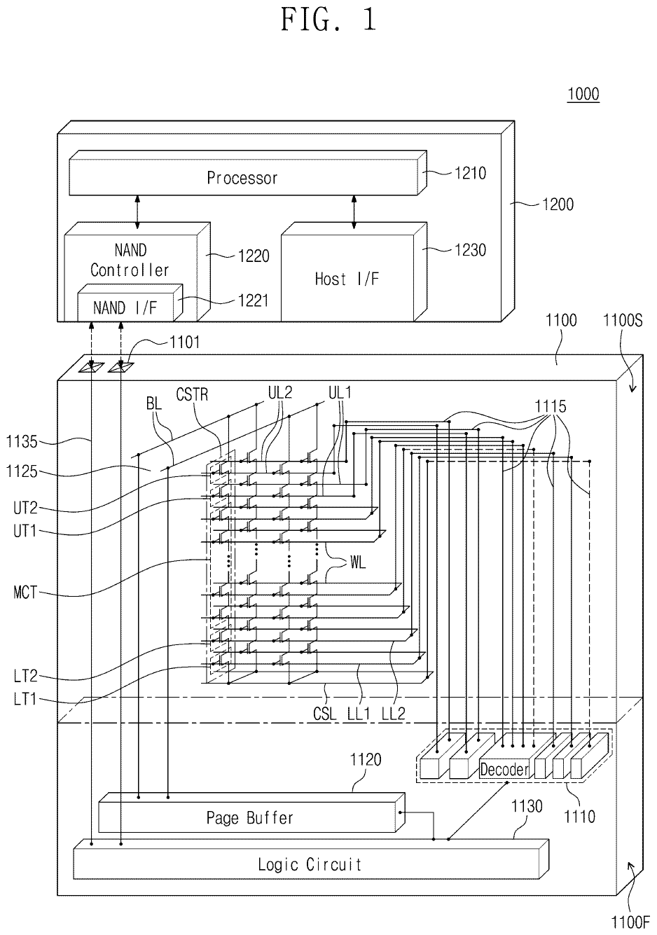

FIG. 1 is a schematic diagram illustrating an electronic system including a semiconductor device, according to some implementations.

Referring to FIG. 1, an electronic system 1000 may include a semiconductor device 1100 and a controller 1200, which is electrically connected to the semiconductor device 1100. The electronic system 1000 may be a storage device, which includes one or more semiconductor devices 1100, or an electronic device including the storage device. For example, the electronic system 1000 may be a solid state drive (SSD) device, a universal serial bus (USB), a computing system, a medical system, or a communication system, in which at least one semiconductor device 1100 is provided.

The semiconductor device 1100 may be a nonvolatile memory device (e.g., a NAND FLASH memory device). The semiconductor device 1100 may include a first structure 1100F and a second structure 1100S on the first structure 1100F. Alternatively, the first structure 1100F may be disposed beside the second structure 1100S.

The first structure 1100F may be a peripheral circuit structure including a decoder circuit 1110, a page buffer 1120, and a logic circuit 1130. The second structure 1100S may be a memory cell structure including bit lines BL, a common source line CSL, word lines WL, first and second gate upper lines UL1 and UL2, first and second gate lower lines LL1 and LL2, and memory cell strings CSTR.

In the second structure 1100S, each of the memory cell strings CSTR may include lower transistors LT1 and LT2 adjacent to the common source line CSL, upper transistors UT1 and UT2 adjacent to the bit lines BL, and a plurality of memory cell transistors MCT disposed between the lower transistors LT1 and LT2 and the upper transistors UT1 and UT2. In some implementations, the number of the lower transistors LT1 and LT2 and the number of the upper transistors UT1 and UT2 may be variously changed.

For example, the upper transistors UT1 and UT2 may include a string selection transistor, and the lower transistors LT1 and LT2 may include a ground selection transistor. The first and second gate lower lines LL1 and LL2 may be used as gate electrodes of the lower transistors LT1 and LT2, respectively. The word lines WL may be the gate electrodes of the memory cell transistors MCT, and the first and second gate upper lines UL1 and UL2 may be the gate electrodes of the upper transistors UT1 and UT2, respectively.

For example, the lower transistors LT1 and LT2 may include a lower erase control transistor and a ground selection transistor, which are connected in series. The upper transistors UT1 and UT2 may include a string selection transistor and an upper erase control transistor, which are connected in series. At least one of the lower and upper erase control transistors may be used to perform an erase operation of erasing data in the memory cell transistors MCT using a gate-induced drain leakage (GIDL) phenomenon.

The common source line CSL, the first and second gate lower lines LL1 and LL2, the word lines WL, and the first and second gate upper lines UL1 and UL2 may be electrically connected to the decoder circuit 1110 through first connection lines 1115, which are extended from the first structure 1100F to the second structure 1100S. The bit lines BL may be electrically connected to the page buffer 1120 through second connection lines 1125, which are extended from the first structure 1100F to the second structure 1100S.

In the first structure 1100F, the decoder circuit 1110 and the page buffer 1120 may be configured to perform a control operation on at least one transistor that is selected from the memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection line 1135, which is extended from the first structure 1100F to the second structure 1100S.

Although not shown, the first structure 1100F may include a voltage generator (not shown). The voltage generator may generate a program voltage, a read voltage, a pass voltage, a verification voltage, and so forth, which are needed to operate the memory cell strings CSTR. Here, the program voltage may be a relatively high voltage (e.g., 20V to 40V), compared with the read voltage, the pass voltage, and the verification voltage.

The first structure 1100F may include high voltage transistors and low voltage transistors. The decoder circuit 1110 may include pass transistors which are connected to the word lines WL of the memory cell strings CSTR. The pass transistors may include high-voltage transistors which can stand a high voltage (e.g., the program voltage) applied to the word lines WL during a programming operation). The page buffer 1120 may also include high-voltage transistors which can stand the high voltage.

The controller 1200 may include a processor 1210, a NAND controller 1220, and a host interface 1230. For example, the electronic system 1000 may include a plurality of semiconductor devices 1100, and in this case, the controller 1200 may control the semiconductor devices 1100.

The processor 1210 may control overall operations of the electronic system 1000 including the controller 1200. The processor 1210 may be operated based on a specific firmware and may control the NAND controller 1220 to access the semiconductor device 1100. The NAND controller 1220 may include a NAND interface 1221, which is used to communicate with the semiconductor device 1100. The NAND interface 1221 may be used to transmit and receive control commands for controlling the semiconductor device 1100 and data to be written in or read from the memory cell transistors MCT of the semiconductor device 1100. The host interface 1230 may be configured to allow for communication between the electronic system 1000 and an external host. When a control command is received from an external host through the host interface 1230, the processor 1210 may control the semiconductor device 1100 in response to the control command.

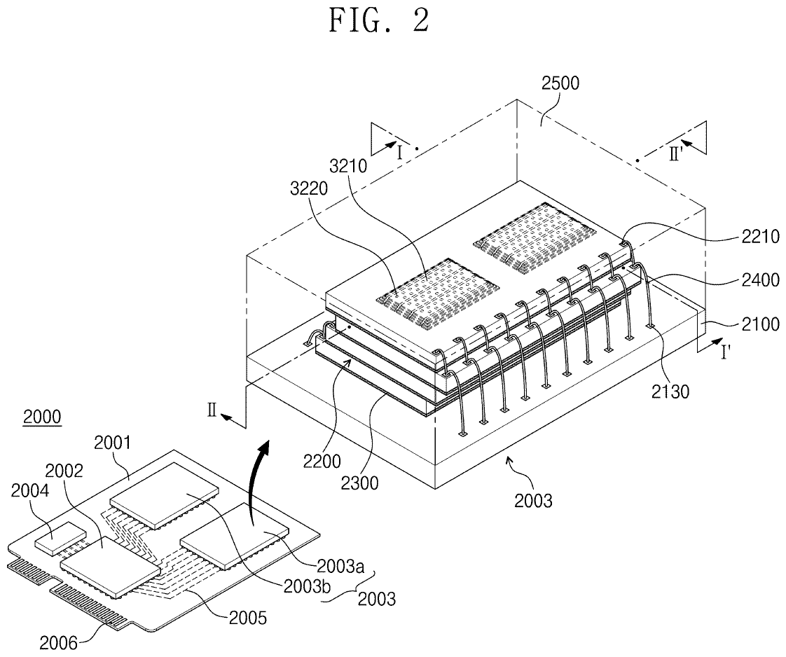

FIG. 2 is a perspective view schematically illustrating an electronic system including a semiconductor device, according to some implementations.

Referring to FIG. 2, an electronic system 2000 may include a main substrate 2001 and a controller 2002, one or more semiconductor packages 2003, and a DRAM 2004, which are mounted on the main substrate 2001. The semiconductor package 2003 and the DRAM 2004 may be connected to the controller 2002 through interconnection patterns 2005 provided in the main substrate 2001.

The main substrate 2001 may include a connector 2006, which includes a plurality of pins coupled to an external host. In the connector 2006, the number and arrangement of the pins may depend on a communication interface between the electronic system 2000 and the external host. For example, the electronic system 2000 may communicate with the external host, in accordance with one of interfaces, such as universal serial bus (USB), peripheral component interconnect express (PCI-Express), serial advanced technology attachment (SATA), universal flash storage (UFS) M-PHY, or the like. In some implementations, the electronic system 2000 may be driven by an electric power, which is supplied from the external host through the connector 2006. The electronic system 2000 may further include a power management integrated circuit (PMIC) that is configured to separately supply an electric power, which is supplied from the external host, to the controller 2002 and the semiconductor package 2003.

The controller 2002 may be configured to control a writing or reading operation on the semiconductor package 2003 and to improve an operation speed of the electronic system 2000.

The DRAM 2004 may be a buffer memory that is configured to relieve technical difficulties caused by a difference in speed between the semiconductor package 2003, which serves as a data storage device, and an external host. In some implementations, the DRAM 2004 in the electronic system 2000 may serve as a cache memory and may be used as a storage space, which is used to temporarily store data during a control operation on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b, which are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 respectively disposed on bottom surfaces of the semiconductor chips 2200, a connection structure 2400 electrically connecting the semiconductor chips 2200 to the package substrate 2100, and a molding layer 2500 disposed on the package substrate 2100 to cover the semiconductor chips 2200 and the connection structure 2400.

The package substrate 2100 may be a printed circuit board including upper pads 2130. Each of the semiconductor chips 2200 may include an input/output pad 2210. The input/output pad 2210 may correspond to the input/output pad 1101 of FIG. 1. Each of the semiconductor chips 2200 may include stacks 3210 and vertical channel structures 3220. Each of the semiconductor chips 2200 may include a three-dimensional semiconductor memory device, which will be described below.

For example, the connection structure 2400 may be bonding wires electrically connecting the input/output pad 2210 to the upper pads 2130. Thus, in each of the first and second semiconductor packages 2003a and 2003b, the semiconductor chips 2200 may be electrically connected to each other through a bonding wire method and may be electrically connected to the upper pads 2130 of the package substrate 2100. In some implementations, the semiconductor chips 2200 in each of the first and second semiconductor packages 2003a and 2003b may be electrically connected to each other by a connection structure including through silicon vias (TSVs), not by the connection structure 2400 provided in the form of bonding wires.

For example, the controller 2002 and the semiconductor chips 2200 may be included in a single package. In some implementations, the controller 2002 and the semiconductor chips 2200 may be mounted on a separate interposer substrate, which is prepared regardless of the main substrate 2001, and may be connected to each other through interconnection lines, which are provided in the interposer substrate.

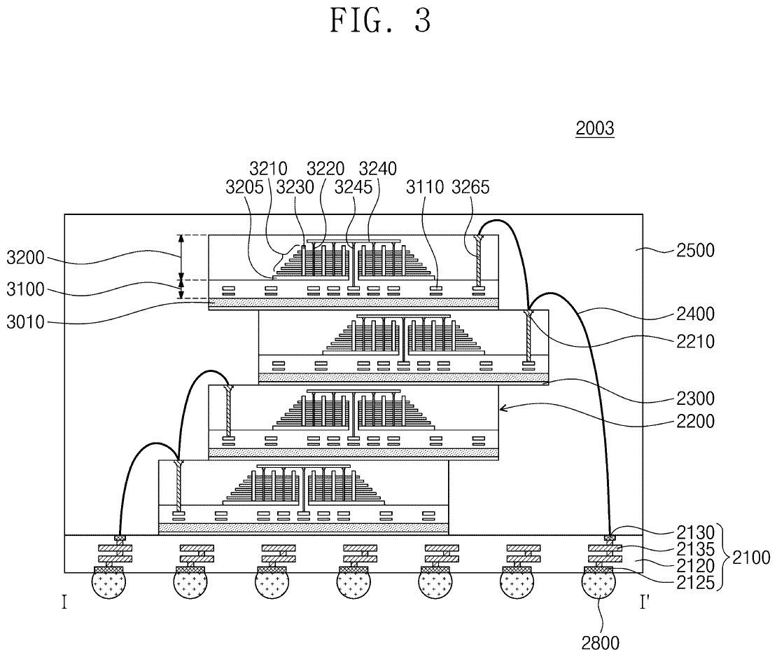

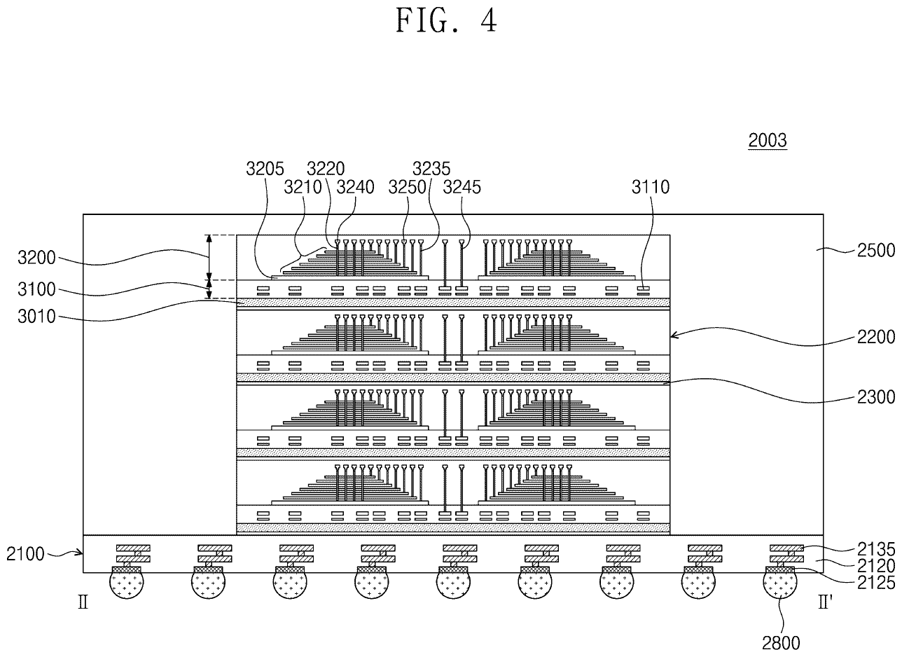

FIGS. 3 and 4 are sectional views, which are taken along lines I-I′ and II-II′ of FIG. 2 to illustrate semiconductor packages including a three-dimensional semiconductor memory device according to some implementations.

Referring to FIG. 3, the semiconductor package 2003 may include the package substrate 2100, the semiconductor chips 2200 on the package substrate 2100, and the molding layer 2500 covering the package substrate 2100 and the semiconductor chips 2200.

The package substrate 2100 may include a package substrate body portion 2120, the package upper pads 2130 disposed on a top surface of the package substrate body portion 2120, lower pads 2125 disposed on or exposed through a bottom surface of the package substrate body portion 2120, and internal lines 2135 provided in the package substrate body portion 2120 to electrically connect the upper pads 2130 to the lower pads 2125. The upper pads 2130 may be electrically connected to the connection structures 2400. The lower pads 2125 may be connected to the interconnection patterns 2005 of the main substrate 2001 of the electronic system 2000 of FIG. 2 through conductive connecting portions 2800.

Each of the semiconductor chips 2200 may include a semiconductor substrate 3010 and a first structure 3100 and a second structure 3200, which are sequentially stacked on the semiconductor substrate 3010. The first structure 3100 may include a peripheral circuit region including peripheral lines 3110. The second structure 3200 may include a common source line 3205, a gate stack 3210 on the common source line 3205, the vertical channel structures 3220 and separation structures 3230 penetrating the gate stack 3210, bit lines 3240 electrically connected to the vertical channel structures 3220, gate connection lines 3235 electrically connected to the word lines WL (e.g., see FIG. 1) of the gate stack 3210, and conductive lines 3250.

Each of the semiconductor chips 2200 may include penetration lines 3245, which are electrically connected to the peripheral lines 3110 of the first structure 3100 and are extended into the second structure 3200. The penetration line 3245 may be provided to penetrate the gate stack 3210 and may be disposed outside the gate stack 3210. Each of the semiconductor chips 2200 may include an input/output connection line 3265, which is electrically connected to the peripheral lines 3110 of the first structure 3100 and is extended into the second structure 3200, and input/output pads 2210, which are electrically connected to the input/output connection line 3265.

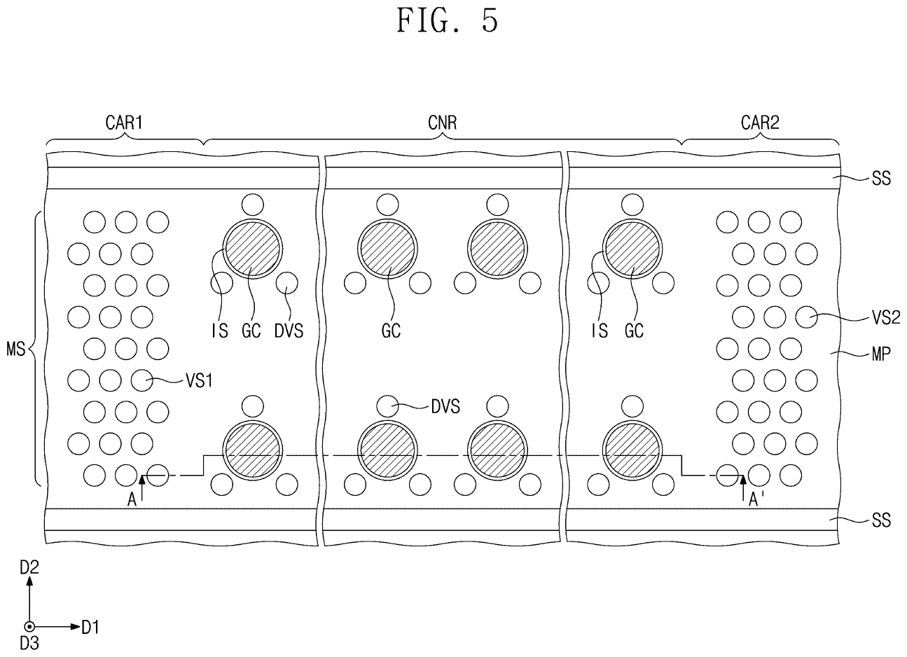

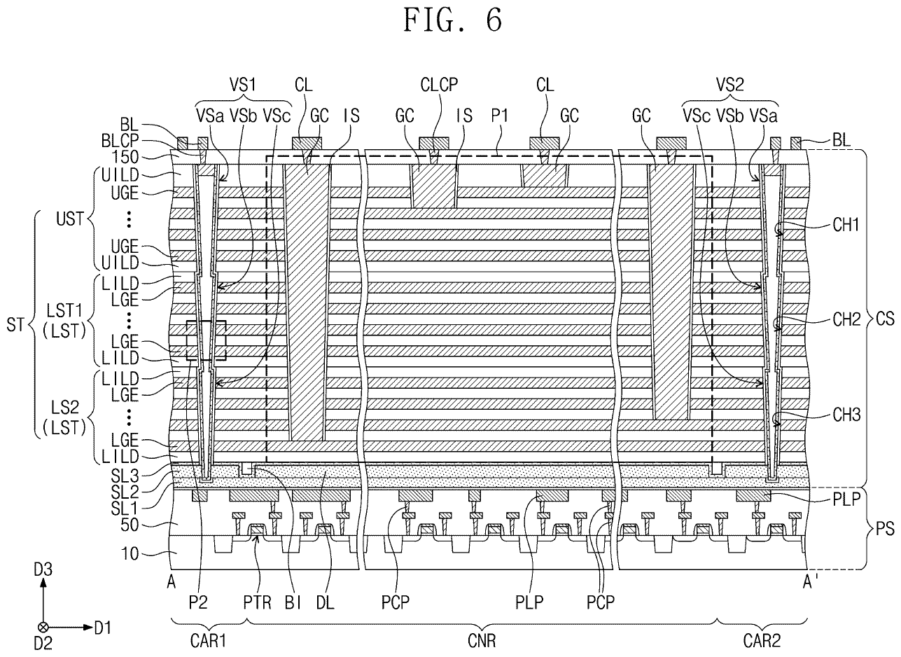

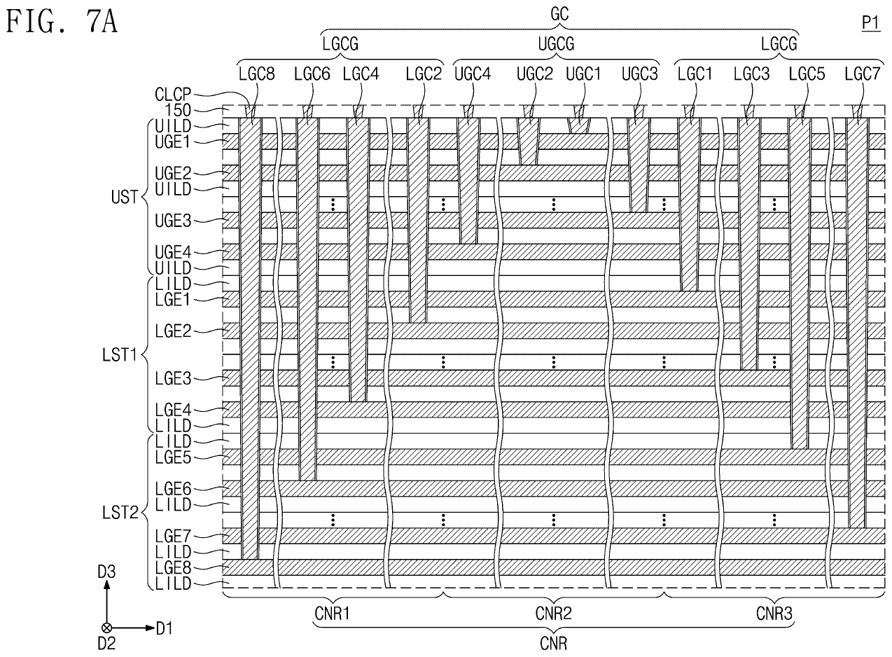

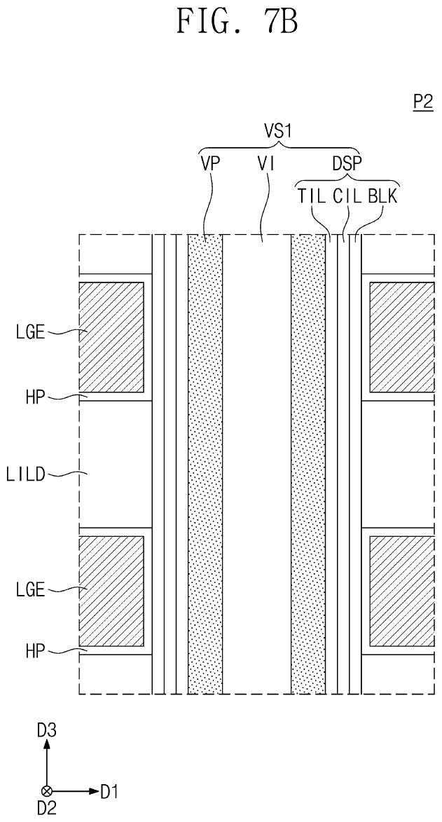

FIG. 5 is a plan view illustrating a semiconductor device according to some implementations. FIG. 6 is a sectional view taken along a line A-A′ of FIG. 5. FIG. 7A is an enlarged view illustrating a portion ‘P1’ of FIG. 6. FIG. 7B is an enlarged view illustrating a portion ‘P2’ of FIG. 6.

Referring to FIGS. 5, 6, and 7A, the semiconductor device may include a peripheral circuit structure PS and a cell array structure CS on the peripheral circuit structure PS.

The peripheral circuit structure PS may include peripheral circuits PTR, peripheral circuit lines PLP, peripheral contact plugs PCP, and a lower insulating layer 50, which are integrated on a front surface of a substrate 10. The substrate 10 may be a plate-shaped structure that is extended parallel to a plane defined by a first direction D1 and a second direction D2. The first and second directions D1 and D2 may not be parallel to each other. As an example, the first and second directions D1 and D2 may be horizontal directions that are orthogonal to each other. The substrate 10 may be a semiconductor substrate, an insulating substrate, a silicon-on-insulator (SOI) substrate, or a germanium-on-insulator (GOI) substrate. The semiconductor substrate may be formed of or include at least one of silicon, germanium, silicon-germanium, GaP, or GaAs. The substrate 10 may include a first cell array region CAR1, a connection region CNR, and a second cell array region CAR2, which are sequentially arranged in the first direction D1.

The peripheral circuits PTR may correspond to the decoder circuit 1110, the page buffer 1120, and the control circuit of FIG. 1. In detail, the peripheral circuits PTR may include NMOS and PMOS transistors. The peripheral circuits PTR may be electrically connected to the peripheral contact plugs PCP. The peripheral circuits PTR may be electrically connected to the peripheral circuit lines PLP through the peripheral contact plugs PCP. For example, the width of the peripheral contact plug PCP in the first or second direction D1 or D2 may increase, as a height in a third direction D3 increases. The peripheral contact plugs PCP and the peripheral circuit lines PLP may be formed of or include at least one of conductive materials (e.g., metallic materials).

The lower insulating layer 50 may be provided on the substrate 10. The lower insulating layer 50 on the substrate 10 may cover the peripheral circuits PTR, the peripheral contact plugs PCP, and the peripheral circuit lines PLP. The lower insulating layer 50 may include a plurality of stacked insulating layers. For example, the lower insulating layer 50 may include a silicon oxide layer, a silicon nitride layer, a silicon oxynitride layer, and/or a low-k dielectric layer.

The cell array structure CS may be disposed on the lower insulating layer 50. The cell array structure CS may include a stack ST, first and second vertical channel structures VS1 and VS2, gate contacts GC, bit lines BL, and connection lines CL.

The cell array structure CS may include first to third source layers SL1, SL2, and SL3 and a dummy layer DL disposed on the lower insulating layer 50. The first to third source layers SL1, SL2, and SL3 may include a conductive material. For example, the first to third source layers SL1, SL2, and SL3 may be formed of or include poly silicon. The second source layer SL2 may be disposed on the first and second cell array regions CAR1 and CAR2. The second source layer SL2 may be a common source line.

The dummy layer DL may be provided on the first source layer SL1. The dummy layer DL may be spaced apart from the second source layer SL2, and a top surface of the dummy layer DL may be coplanar with a top surface of the second source layer SL2. The dummy layer DL may have a multi-layered structure, which includes a plurality of layers stacked on the first source layer SL1. In some implementations, the dummy layer DL may be formed of or include at least one of insulating materials (e.g., oxide and/or nitride materials).

The third source layer SL3 may cover the second source layer SL2 and the dummy layer DL. The third source layer SL3 may be disposed on the first and second cell array regions CAR1 and CAR2 and the connection region CNR.

An insulating gapfill layer BI may be disposed on the third source layer SL3. The insulating gapfill layer BI may be disposed between the first cell array region CAR1 and the connection region CNR and between the second cell array region CAR2 and the connection region CNR. The insulating gapfill layer BI may be provided between the dummy layer DL and the second source layer SL2. The second source layer SL2 and the dummy layer DL may be spaced apart from each other in the first direction D1, and the insulating gapfill layer BI and a portion of the third source layer SL3 enclosing the insulating gapfill layer BI may be interposed between the second source layer SL2 and the dummy layer DL. The insulating gapfill layer BI may include an insulating material.

The stack ST may be disposed on the third source layer SL3. The stack ST may have a uniform thickness on the first and second cell array regions CAR1 and CAR2 and the connection region CNR and may be extended in the first direction D1.

The stack ST may include a lower stack LST stacked on the third source layer SL3 and an upper stack UST on the lower stack LST. The lower stack LST may include first and second lower stacks LST1 and LST2, as shown in FIG. 6, b. In some examples, the lower stack LST may be configured to include two or more lower stacks or may be provided as a single stack. In the present specification, the description that follows will refer to an example, in which two lower stacks LST1 and LST2 are stacked, for convenience in description.

The upper stack UST may include upper gate electrodes UGE and upper insulating layers UILD, which are alternately stacked in the third direction D3 (i.e., a vertical direction), which is perpendicular to the first and second directions D1 and D2. Each of the upper gate electrodes UGE may have substantially the same thickness.

The lower stack LST may include lower gate electrodes LGE and lower insulating layers LILD alternately stacked in the third direction D3 (i.e., a vertical direction). Each of the lower gate electrodes LGE may have substantially the same thickness.

For example, the upper and lower gate electrodes UGE and LGE may be formed of or include at least one of doped semiconductor materials (e.g., doped silicon), metallic materials (e.g., tungsten, copper, or aluminum), conductive metal nitride materials (e.g., titanium nitride or tantalum nitride), or transition metal materials (e.g., titanium or tantalum). The upper and lower insulating layers UILD and LILD may be formed of or include at least one of silicon oxide and/or low-k dielectric materials.

The upper and lower gate electrodes UGE and LGE and the upper and lower insulating layers UILD and LILD may be extended in the first direction D1 and may have substantially the same length in the first direction D1. That is, the upper and lower gate electrodes UGE and LGE and the upper and lower insulating layers UILD and LILD may have substantially the same horizontal length. In other words, the stack ST may not have a staircase structure, on the connection region CNR. Thus, the length of the stack ST in the first direction D1 may decrease on the connection region CNR. Accordingly, it may be possible to reduce the size of the semiconductor device.

In some implementations, the semiconductor device may be a vertical-type NAND FLASH memory device. In this case, the upper and lower gate electrodes UGE and LGE of the stack ST may be used as the gate electrodes of the string selection transistor, the memory cell transistors, and the ground selection transistors of FIG. 1.

The first vertical channel structures VS1 may be provided on the first cell array region CAR1 to penetrate the stack ST. The second vertical channel structures VS2 may be provided to penetrate the stack ST, on the second cell array region CAR2. When viewed in a plan view, the first and second vertical channel structures VS1 and VS2 may be arranged in a specific direction or in a zigzag shape.

Each of the first and second vertical channel structures VS1 and VS2 may include a first portion VSa penetrating the upper stack UST, a second portion VSb penetrating the first lower stack LST1, and the second portion VSb penetrating the second lower stack LST2. The first to third portions VSa, VSb, and VSc may be defined as portions of the first and second vertical channel structures VSa and VSb placed in the first to third channel holes CH1, CH2, and CH3, respectively. Each of the first to third channel holes CH1, CH2, and CH3 may have a decreasing width, as a distance from the substrate 10 decreases. For example, each of the first to third portions VSa, VSb, and VSc may have the largest width at its top level. As an example, a bottom width of the first portion VSa may be smaller than a top width of the second portion VSb, and a bottom width of the second portion VSb may be smaller than a top width of the third portion VSc.

Referring to FIG. 7B, each of the first and second vertical channel structures VS1 and VS2 may include a vertical semiconductor pattern VP, a data storage pattern DSP enclosing a side surface of the vertical semiconductor pattern VP, and a gapfill insulating pattern VI in the vertical semiconductor pattern VP.

For example, the vertical semiconductor pattern VP may have a pipe or macaroni shape with closed bottom. The vertical semiconductor pattern VP may have a U-shaped structure, and an inner space of the vertical semiconductor pattern VP may be filled with the gapfill insulating pattern VI. A bit line conductive pad may be formed on the vertical semiconductor pattern VP and may be formed of or include at least one of undoped or doped semiconductor materials or conductive materials.

The vertical semiconductor pattern VP may be formed of or include at least one of semiconductor materials (e.g., silicon (Si) or germanium (Ge)). The vertical semiconductor pattern VP including the semiconductor material may be used as the channel patterns of the memory cell transistors constituting the cell string.

The data storage pattern DSP may be extended in the third direction D3 to enclose the side surface of each of the vertical semiconductor patterns VP. The data storage pattern DSP may be a pipe-or macaroni-shape pattern with open top and bottom. The data storage pattern DSP may be composed of one or more layers. In some implementations, the data storage pattern DSP may be a data storing layer of a NAND FLASH memory device and may include a tunnel insulating layer TIL, a charge storing layer CIL, and a blocking insulating layer BLK, which are sequentially stacked on the side surface of the vertical semiconductor pattern VP. For example, the charge storing layer CIL may be a trap insulating layer, a floating gate electrode, or an insulating layer with conductive nanodots. In detail, the charge storing layer CIL may include at least one of a silicon nitride layer, a silicon oxynitride layer, a silicon-rich nitride layer, a nanocrystalline silicon layer, or a laminated trap layer. The tunnel insulating layer TIL may be formed of at least one of materials, whose band gaps are greater than the charge storing layer CIL, and the blocking insulating layer BLK may be formed of a high-k dielectric material (e.g., aluminum oxide and hafnium oxide).

A horizontal insulating pattern HP may be provided between the side surfaces of the lower or upper gate electrode LGE or UGE and the data storage pattern DSP. The horizontal insulating pattern HP may be extended from the side surfaces of the lower or upper gate electrode LGE or UGE to cover top and bottom surfaces of the lower or upper gate electrode LGE or UGE. For example, the horizontal insulating pattern HP may be formed of or include at least one of silicon oxide and/or high-k dielectric materials.

Referring back to FIGS. 5, 6, and 7A, a plurality of dummy vertical structures DVS may be provided on the connection region CNR to penetrate the stack ST. The dummy vertical structures DVS may be placed to be adjacent to the gate contacts GC. In some examples, the dummy vertical structures DVS and the first and second vertical channel structures VS1 and VS2 may be formed through the same process and may substantially have the same structure. The dummy vertical structures DVS may be used to support the insulating layers UILD and LILD of the stack ST in a fabrication process to be described below.

The gate contacts GC may be provided on the connection region CNR. Each of the gate contacts GC may be provided to penetrate a portion of the stack ST and may be connected to one of the upper or lower gate electrodes UGE and LGE. For example, the gate contacts GC may be formed of or include at least one of metallic materials (e.g., tungsten, copper, or aluminum), conductive metal nitride materials (e.g., titanium nitride or tantalum nitride), or transition metal materials (e.g., titanium or tantalum).

Insulating patterns IS may be provided between the gate contacts GC and the stack ST. When viewed in a plan view, the insulating patterns IS may enclose each of the gate contacts GC. The insulating patterns IS may be in direct contact with side surfaces of the gate contacts GC. Top surfaces of the insulating patterns IS may be positioned at substantially the same level as top surfaces of the gate contacts GC. For example, the insulating patterns IS may be formed of or include at least one of silicon oxide, silicon nitride, silicon oxynitride, or low-k dielectric materials.

Referring to FIGS. 6 and 7A, the connection region CNR may include a first connection region CNR1, a second connection region CNR2, and a third connection region CNR3 in the first direction D1. The first connection region CNR1 may be adjacent to the first cell array region CAR1 in the first direction D1, and the third connection region CNR3 may be adjacent to the second cell array region CAR2 in the first direction D1. That is, the second connection region CNR2 may indicate a center region of the connection region CNR, which is spaced apart from the first and second cell array regions CAR1 and CAR2 in the first direction D1.

The gate contacts GC may include upper gate contacts UGCG and lower gate contacts LGCG. The upper gate contacts UGCG may be provided to penetrate the upper stack UST at least partially and may be connected to the upper gate electrodes UGE. Lower gate contacts LGC may be provided to penetrate the lower stack LST at least partially and may be connected to the lower gate electrodes LGE.

In the following description of FIG. 7A, the upper gate electrodes UGE may be referred to as first to fourth upper gate electrodes UGE1 to UGE4 along the vertical level, and the lower gate electrodes LGE may be referred to as first to eighth lower gate electrodes LGE1 to LGE8 along the vertical level, for convenience in description. The first to fourth upper gate electrodes UGE1 to UGE4 may indicate the upper gate electrodes in the upper stack UST, first to fourth lower gate electrodes LGE1 to LGE4 may indicate the lower gate electrodes in the first lower stack LST1, and fifth to eighth lower gate electrodes LGE5 to LGE8 may indicate the lower gate electrodes in the second lower stack LST2.

The upper gate contacts UGCG connected to the upper gate electrodes UGE may be disposed on the second connection region CNR2. The lower gate contacts LGCG connected to the lower gate electrodes LGE may be disposed on the first and third connection regions CNR1 and CNR3. A vertical length of each of the upper gate contacts UGCG may be shorter than a vertical length of each of the lower gate contacts LGCG. The lower gate contacts LGCG may be provided to penetrate the upper gate electrodes UGE and may be connected to the lower gate electrodes LGE. Top surfaces of the upper gate contacts UGCG may be coplanar with top surfaces of the lower gate contacts LGCG.

The upper gate contacts UGCG may include first to fourth upper gate contacts UGC1 to UGC4, which are connected to the first to fourth upper gate electrodes UGE1 to UGE4, respectively. The lower gate contacts LGCG may include first to eighth lower gate contacts LGC1 to LCG8, which are connected to the first to eighth lower gate electrodes LGE1 to LGE8, respectively. The first to fourth upper gate contacts UGC1 to UGC4 and the first to eighth lower gate contacts LGC1 to LGC8 may be arranged in the first direction D1.

The first to fourth upper gate contacts UGC1 to UGC4 may be disposed on the second connection region CNR2. The first to eighth lower gate contacts LGC1 to LGC8 may be appropriately arranged in the first and third connection regions CNR1 and CNR3. As an example, the second, fourth, sixth, eighth lower gate contacts LCG2, LCG4, LCG6, and LCG8 may be disposed on the first connection region CNR1, and the first, third, fifth and seventh lower gate contacts LGC1, LCG3, LCG5, and LCG7 may be disposed on the third connection region CNR3.

The first upper gate contact UGC1 may be connected to the first upper gate electrode UGE1, which is provided as the topmost one of the upper gate electrodes UGE. The second upper gate contact UGC2 may be connected to the second upper gate electrode UGE2, which is one of upper electrodes of the upper gate electrodes UGE. The third and fourth upper gate contacts UGC3 and UGC4 may be disposed between the first and second upper gate contacts UGC1 and UGC2 and the lower gate contacts LGCG.

A vertical length of the first upper gate contact UGC1 may be smaller than a vertical length of each of other upper gate contact UGE. For example, the vertical length of the first upper gate contact UGC1 may be shorter than the vertical length of each of the second to fourth upper gate contacts UGC2 to UGC4. A vertical length of the second upper gate contact UGC2 may be longer than the vertical length of the first upper gate contact UGC1 and may be shorter than a vertical length of each of the third and fourth upper gate contacts UGC3 and UGC4. The third and fourth upper gate contacts UGC3 and UGC4 may be connected to the third and fourth upper gate electrodes UGE3 and UGE4, respectively, which are disposed therebelow. The vertical length of each of the first to fourth upper gate contacts UGC1 to UGC4 may be shorter than the vertical length of each of the lower gate contacts LGCG.

Remaining ones of the upper gate contacts UGCG may be disposed between the first and second upper gate contacts UGC1 and UGC2 and the third and fourth upper gate contacts UGC3 and UGC4. The remaining ones of the upper gate contacts UGCG may be connected to the upper gate electrodes UGE, which are disposed between the second upper gate electrode UGE2 and the third upper gate electrode UGE3.

The number of the gate contacts GC penetrating the upper gate electrodes UGE may be greater than the number of the gate contacts GC penetrating the lower gate electrodes LGE. Thus, each of the upper gate electrodes UGE may have a smaller sectional area and a larger resistance value, compared to each of the lower gate electrodes LGE. In particular, the first upper gate electrode GE1 may have the largest resistance and may have a larger resistance than that of each of the lower gate electrodes LGE. This may result in a reduction in the transmission speed of signals (e.g., voltages), which are transmitted the first or second vertical channel structure VS1 and VS2 through the upper gate electrodes UGE. As an example, if the upper gate contacts UGCG connected to the upper gate electrodes UGE are disposed on the first or third connection region CNR1 or CNR3 to be adjacent to the first or second cell array regions VS1 and VS2, the transmission speed of signals, which are transmitted to the first or second vertical channel structure VS1 or VS2 placed on a remaining portion of the cell array region, may decrease. Thus, the overall operation speed of the memory cells may decrease.

By contrast, according to some implementations, upper gate contacts UGC, which are connected to the upper gate electrodes UGE with relatively large resistance, may be disposed on the second connection region CNR2, which is an intermediate region of the connection region CNR. In this case, as described above, the resistance between the upper gate contacts UGCG and the first or second vertical channel structures VS1 and VS2 may be prevented from increasing beyond a desired range. Accordingly, the overall operation speed of the memory cell as well as the electrical and reliability characteristics of the semiconductor device may be improved.

Referring back to FIGS. 5 and 6, each of separation structures SS may be extended in the first direction D1. The separation structures SS may be spaced apart from each other in the second direction D2 crossing the first direction D1. The separation structures SS may be provided to penetrate at least portion of the stack ST. Each of the separation structures SS may be formed of or include an insulating material and may have a single-or multi-layered structure.

A first interlayer insulating layer 150 may be provided on the stack ST. The first interlayer insulating layer 150 may cover the uppermost one of the upper insulating layers UILD, the first and second vertical channel structures VS1 and VS2, and the gate contacts GC.

In the first and second cell array regions CAR1 and CAR2, the bit lines BL may be provided on the first interlayer insulating layer 150. Each of the bit lines BL may be extended in the second direction D2. The bit lines BL may be spaced apart from each other in the first direction D1. The bit lines BL may be electrically connected to the vertical channel structures VS through bit line contact plugs BLCP.

On the connection region CNR, the connection lines CL may be provided on the first interlayer insulating layer 150. Each of the connection lines CL may be extended in the second direction D2. The connection lines CL may be spaced apart from each other in the first or second direction D1 or D2. The connection lines CL may be electrically connected to the gate contacts GC through connection line contact plugs CLCP.

Semiconductor devices according to some implementations will be described below, and the same element as that in the previous implementation will be identified with the same reference number without repeating the overlapping description.

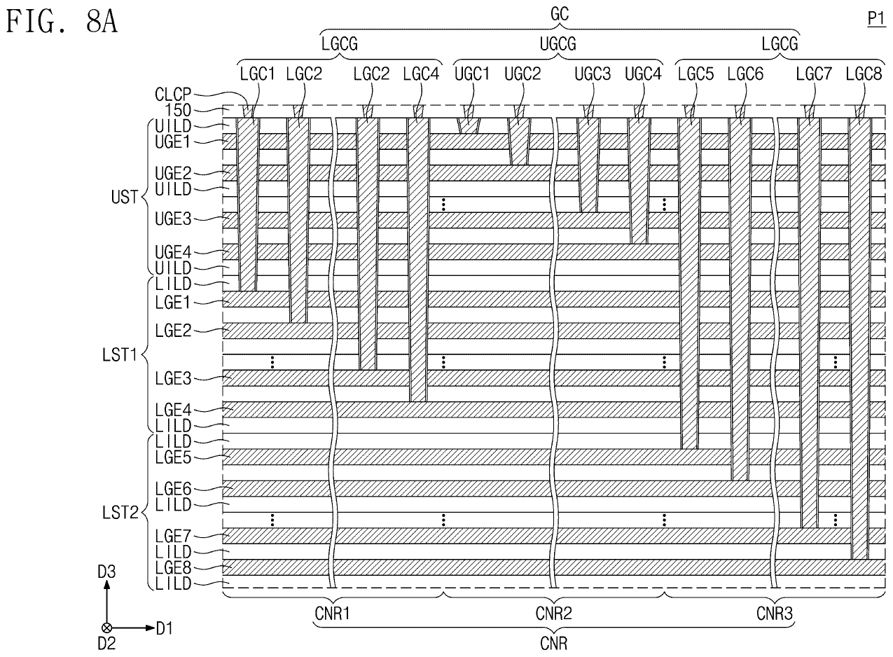

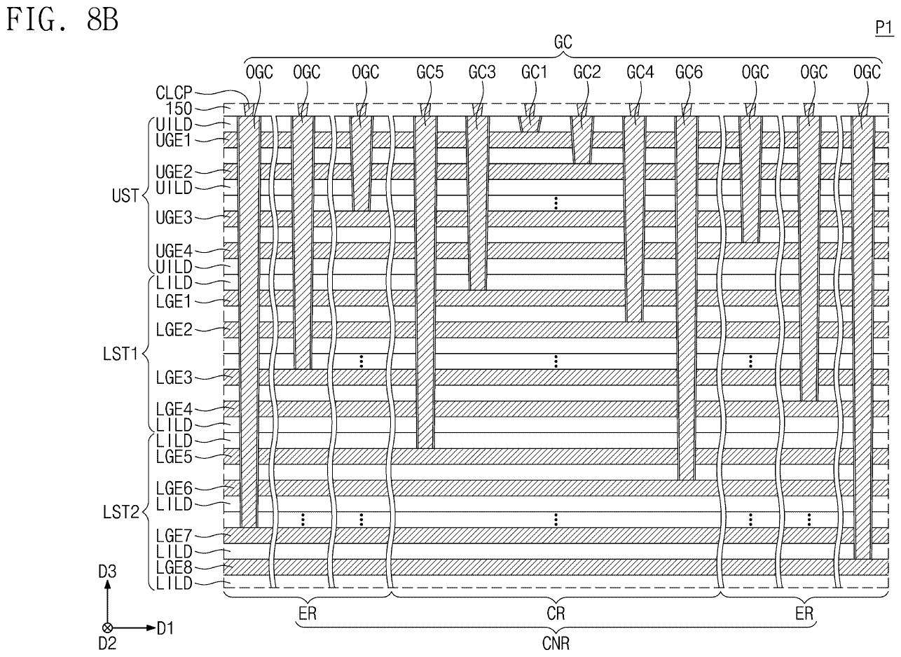

FIGS. 8A and 8B are enlarged sectional views illustrating a semiconductor device according to some implementations and corresponding to FIG. 7A.

Referring to FIG. 8A, the first to fourth lower gate contacts LGC1 to LGC4 may be sequentially disposed on the first connection region CNR1 along the first direction D1. The first to fourth lower gate contacts LGC1 to LGC4 may be connected to corresponding ones of the first to fourth lower gate electrodes LGE1 to LGE4 of the first lower stack LST1.

The first to fourth upper gate contacts UGC1 to UGC4 may be sequentially disposed on the second connection region CNR2 along the first direction D1. The first to fourth upper gate contacts UGC1 to UGC4 may be connected to corresponding ones of the first to fourth upper gate electrodes UGE1 to UGE4 of the upper stack UST.

The fifth to eighth lower gate contacts LGC5 to LGC8 may be sequentially disposed on the third connection region CNR3 along the first direction D1. The fifth to eighth lower gate contacts LGC5 to LGC8 may be connected to corresponding ones of the fifth to eighth lower gate electrodes LGE5 to LGE8 of the second lower stack LST2.

Referring to FIG. 8B, the connection region CNR may include outer regions ER, which are adjacent to the first and second cell array regions CAR1 and CAR2 along the first direction D1, a center region CR between the outer regions ER. The outer regions ER may correspond to the first and third connection regions CNR1 and CNR3 described with reference to FIG. 7A, and the center region CR may correspond to the second connection region CNR2 described with reference to FIG. 7A.

The first and second gate contacts GC1 and GC2 may be disposed on the center region CR and may be connected to the upper gate electrodes UGE1 and UGE2, which are disposed in an upper portion of the upper stack UST. In addition, the third to sixth gate contacts GC3 to GC6 may be disposed on the center region CR and may be connected to the lower gate electrodes LGE1, LGE2, LGE5, and LGE6, which are disposed in upper portions of the first and second lower structures LST1 and LST2. Outer gate contacts OGC may be disposed on the outer regions ER and at different vertical levels from the first to sixth gate contacts GC1 to GC6 described above. The outer gate contacts OGC may be connected to the upper and lower gate electrodes UGE3, UGE4, LGE3, LGE4, LGE7, and LGE8, which are not connected to the first to sixth gate contacts GC1 to GC6.

In some implementations, in the case where the first to third portions (e.g., VSa, VSb, and VSc of FIG. 6) of each of the first and second vertical channel structures (e.g., VS1 and VS2 of FIG. 6) are formed to have large upper portions, the upper and lower gate electrodes (e.g., UGE and LGE of FIG. 6), which are formed in an upper portion of each of the upper and lower stacks (e.g., UST and LST of FIG. 6), may have a reduced sectional area. That is, in each of the upper stack UST and the first lower and second lower stacks LST1 and LST2, the first and second upper gate electrodes UGE1 and UGE2 and the first, second, fifth, and sixth lower gate electrodes LGE1, LGE2, LGE5, and LGE6 may have higher electric resistance than the remaining gate electrodes. In some implementations, since the first to sixth gate contacts GC1 to GC6 connected to the gate electrodes with a large resistance are disposed on the center region CR, it may be possible to prevent the resistance between the first to sixth gate contacts GC1 to GC6 and the first or second vertical channel structures VS1 or VS2 from increasing beyond a desired range.

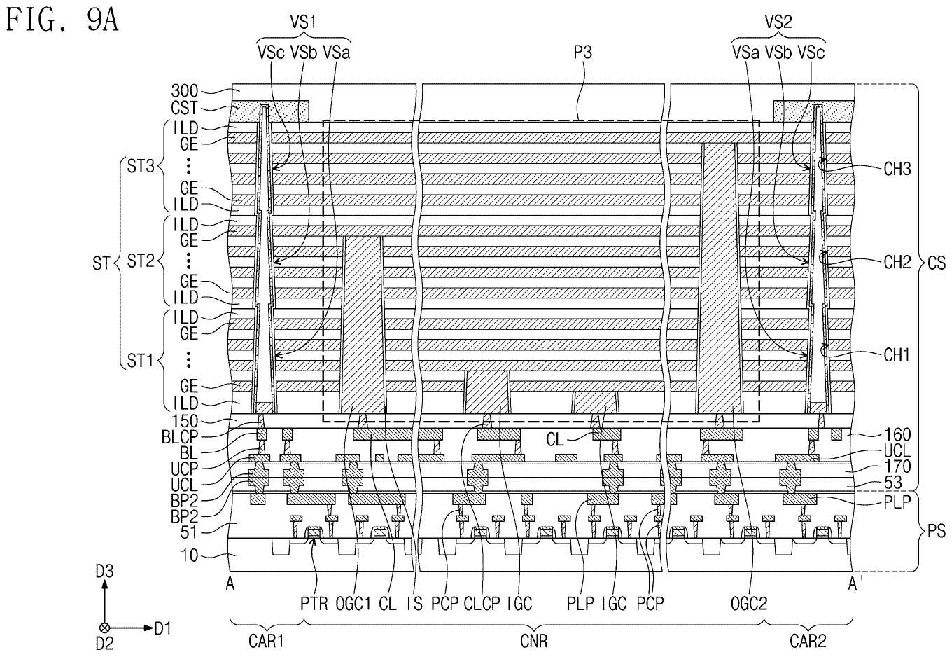

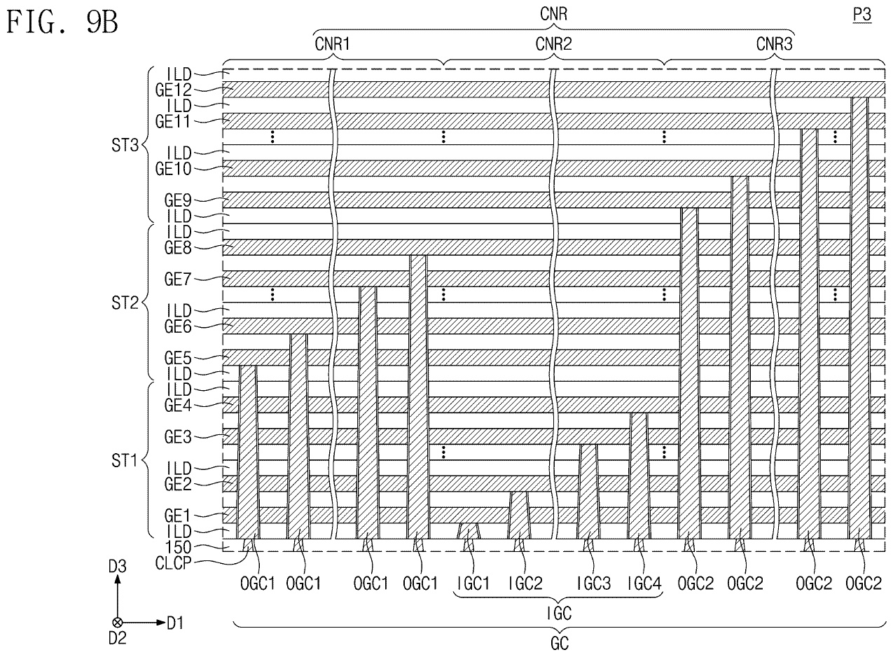

FIG. 9A is a sectional view illustrating a semiconductor device according to some implementations. FIG. 9B is an enlarged view illustrating a portion ‘P3’ of FIG. 9A.

Referring to FIG. 9A, the semiconductor device may have a chip-to-chip (C2C) structure In the C2C structure, an upper chip including the cell array structure CS may be fabricated on a first wafer, a lower chip including the peripheral circuit structure PS may be fabricated on a second wafer different from the first wafer, and the upper chip and the lower chip may be connected to each other through a bonding method. In the bonding method, a bonding metal, which is formed in the uppermost metal layer of the upper chip, may be electrically connected to a bonding metal, which is formed in the uppermost metal layer of the lower chip. In the case where the bonding metal is copper (Cu), the bonding method may be a Cu-to-Cu bonding method, but in some implementations the bonding metal may be aluminum (Al) or tungsten (W).

According to some implementations, the semiconductor device may include the peripheral circuit structure PS and the cell array structure CS on the peripheral circuit structure PS. Since the cell array structure CS is placed on and bonded to the peripheral circuit structure PS, the cell capacity per unit area of the semiconductor device may be increased. In addition, the peripheral circuit structure PS and the cell array structure CS may be separately fabricated and then may be coupled to each other, and in this case, it may be possible to prevent peripheral circuits PTR from being damaged by several thermal treatment processes. Accordingly, it may be possible to improve the electrical and reliability characteristics of the three-dimensional semiconductor memory device.

The peripheral circuit structure PS may include the substrate 10, the peripheral circuits PTR controlling a memory cell array, the peripheral circuit lines PLP, the peripheral contact plugs PCP, and lower insulating layers 51 and 53 on the substrate 10. The peripheral circuits PTR may be integrated on a top surface of the substrate 10.

The lower insulating layers 51 and 53 may be provided on the top surface of the substrate 10. The lower insulating layers 51 and 53 may include a first lower insulating layer 51 and a second lower insulating layer 53. The first lower insulating layer 51 may be provided on the substrate 10 to cover the peripheral circuits PTR, the peripheral contact plugs PCP, and the peripheral circuit lines PLP. The second lower insulating layer 53 may be placed on the first lower insulating layer 51 to cover the first lower insulating layer 51. An etch stop layer may be provided between the second lower insulating layer 53 and the first lower insulating layer 51. For example, the lower insulating layers 51 and 53 may be formed of or include at least one of silicon oxide, silicon nitride, silicon oxynitride, and/or low-k dielectric materials.

First bonding pads BP1 may be provided in the second lower insulating layer 53. The second lower insulating layer 53 may not cover top surfaces of the first bonding pads BP1. In other words, a top surface of the second lower insulating layer 53 may be substantially coplanar with the top surfaces of the first bonding pads BP1. The first bonding pads BP1 may be electrically connected to the peripheral circuits PTR through the peripheral circuit lines PLP and the peripheral contact plugs PCP.

The cell array structure CS may be provided on the peripheral circuit structure PS. The cell array structure CS may include a memory cell array, in which memory cells are three-dimensionally arranged. The cell array structure CS may include the stack ST, the first and second vertical channel structures VS1 and VS2, the gate contacts GC, the bit lines BL, and the connection lines CL, as described with reference to FIGS. 5 and 6.

The stack ST may include the first to third stacks ST1, ST2, and ST3, and each of the first to third stacks ST1 to ST3 may include gate electrodes GE and insulating layers ILD, which are alternately stacked. The first to third stacks ST1 to ST3 may correspond to the upper stack UST and the first and second lower stacks LST1 and LST2, respectively, described with reference to FIGS. 5 and 6.

Each of the first and second vertical channel structures VS1 and VS2 may include the first to third portions VSa, VSb, and VSc penetrating the first to third stacks ST1, ST2, and ST3. Each of the first to third portions VSa, VSb, and VSc may have its largest width at its bottom level. For example, a top width of the first portion VSa may be smaller than a bottom width of the second portion VSb, and a top width of the second portion VSb may be smaller than a bottom width of the third portion VSc.

First to third interlayer insulating layers 150, 160, and 170 may be provided on a bottom surface of the stack ST. The second interlayer insulating layer 160 may cover the bit lines BL and the connection lines CL. Upper conductive lines UCL may be provided in the second interlayer insulating layer 160. The upper conductive lines UCL may be electrically connected to the bit lines BL or the connection lines CL. The third interlayer insulating layer 170 may be provided on the second interlayer insulating layer 160. For example, the first to third interlayer insulating layers 150, 160, and 170 may be formed of or include at least one of silicon oxide, silicon nitride, silicon oxynitride, and/or low-k dielectric materials.

Second bonding pads BP2 may be provided in the third interlayer insulating layer 170. The second bonding pads BP2 may be electrically connected to the upper conductive lines UCL. The second bonding pads BP2 may be electrically and physically connected to the first bonding pads BP1 in a hybrid bonding manner. In the present specification, the hybrid bonding structure may mean a bonding structure which is formed by two materials, which are of the same kind and are fused at an interface therebetween. For example, the first and second bonding pads BP1 and BP2, which are bonded to each other, may have a continuous structure, and there may be no observable interface between the first and second bonding pads BP1 and BP2. The first and second bonding pads BP1 and BP2 may be bonded to form a single object.

A source conductive pattern CST and an upper insulating layer 300 may be disposed on the stack ST. The source conductive pattern CST may be connected to the first and second vertical channel structures VS1 and VS2. The source conductive pattern CST may be provided on the first and second cell array regions CAR1 and CAR2 and may be formed of or include, for example, poly silicon. The upper insulating layer 300 may cover the source conductive pattern CST and the stack ST. The upper insulating layer 300 may be formed of or include at least one of silicon oxide, silicon nitride, silicon oxynitride, and/or low-k dielectric materials.

Referring to FIG. 9B, the gate contacts GC may include first outer gate contacts OGC1, inner gate contacts IGC, and second outer gate contacts OGC2.

The first outer gate contacts OGC1 may be connected to the gate electrodes GE5 to GE8 of the second stack ST2, on the first connection region CNR1. The first outer gate contacts OGC1 may be provided to penetrate the first and second stacks ST1 and ST2 at least partially. The first outer gate contacts OGC1 may be provided to penetrate the gate electrodes GE1 to GE4 of the first stack ST1.

The second outer gate contacts OGC2 may be connected to gate electrodes GE9 to GE12 of the third stack ST3. The second outer gate contacts OGC2 may be provided to penetrate the first to third stacks ST1, ST2, and ST3 at least partially. The second outer gate contacts OGC2 may be provided to penetrate gate electrodes GE1 to GE8 of the first and second stacks ST1 and ST2. The first and second outer gate contacts OGC1 and OGC2 may correspond to the lower gate contacts LGCG described with reference to FIG. 8A.

The inner gate contacts IGC disposed on the second connection region CNR2 may be connected to the gate electrodes GE1 to GE4 of the first stack ST1. The inner gate contacts IGC may be provided to penetrate the first stack ST1 at least partially. The vertical length of each of the inner gate contacts IGC may be smaller than the vertical length of each of the first and second outer gate contacts OGC1 and OGC2. Bottom surfaces of the inner gate contacts IGC may be coplanar with those of the first and second outer gate contacts OGC1 and OGC2.

The inner gate contacts IGC may include first to fourth inner gate contacts IGC1 to IGC4. The first to fourth inner gate contacts IGC1 to IGC4 may be connected to the gate electrodes GE1 to GE4, respectively, of the first stack ST1 and may have different vertical lengths.

Since the first and second outer gate contacts OGC1 and OGC2 are provided to penetrate the gate electrodes GE1 to GE4 of the first stack ST1, the gate electrodes GE1 to GE4 of the first stack ST1 may have a smaller sectional area than the gate electrodes GE5 to GE12 of the second and third stacks ST2 and ST3. Thus, the resistance of the gate electrodes GE1 to GE4 of the first stack ST1 may be greater than that of the gate electrodes GE5 to GE12 of the second and third stacks ST2 and ST3.

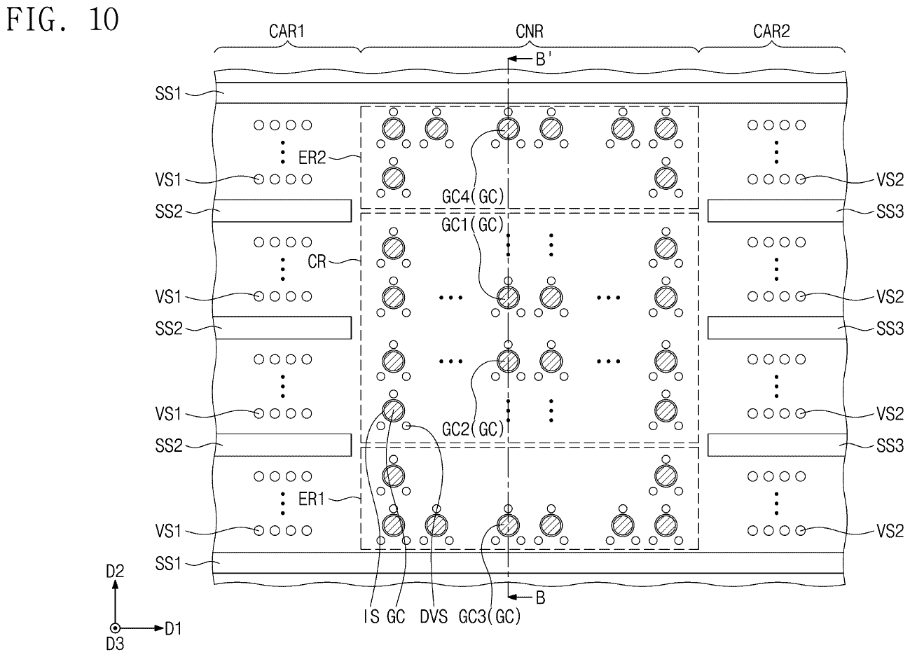

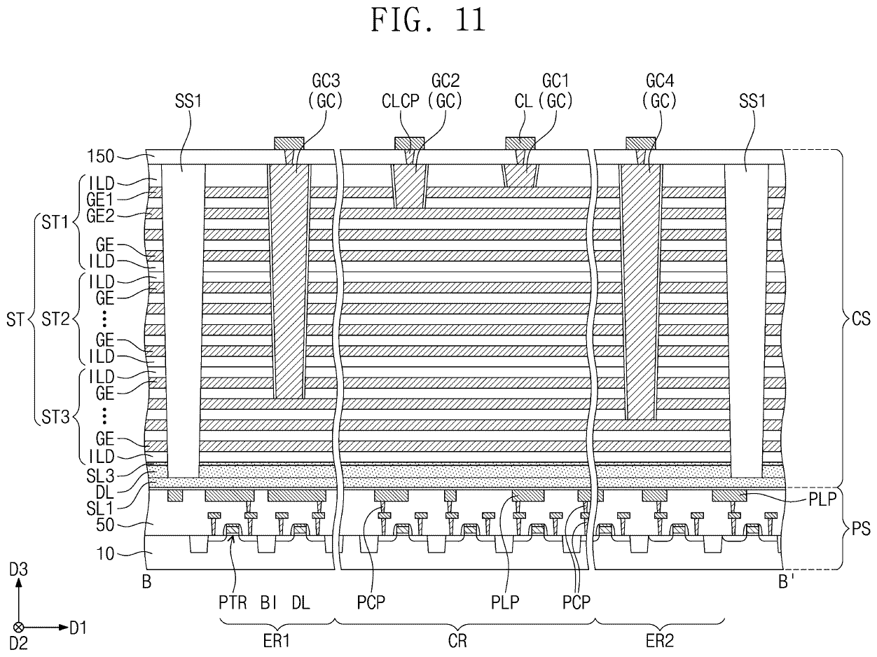

FIG. 10 is a plan view illustrating a semiconductor device according to some implementations. FIG. 11 is a sectional view taken along a line B-B′ of FIG. 10.

Referring to FIGS. 10 and 11, the semiconductor device may include the peripheral circuit structure PS and the cell array structure CS on the peripheral circuit structure PS.

The peripheral circuit structure PS may include the peripheral circuits PTR, the peripheral circuit lines PLP, the peripheral contact plugs PCP, and the lower insulating layer 50, which are integrated on the front surface of the substrate 10.

The cell array structure CS may be disposed on the lower insulating layer 50. The cell array structure CS may include the stack ST, the first and second vertical channel structures VS1 and VS2, the gate contacts GC, the bit lines BL, and the connection lines CL. The stack ST may include the first to third stacks ST1, ST2, and ST3. The first to third stacks ST1, ST2, and ST3 may be substantially the same as the upper stacks UST and the first and second lower stacks LST1 and LST2, respectively, described with reference to FIGS. 5 and 6. Each of the first to third stacks ST1, ST2, and ST3 may include gate electrodes GE and insulating layers ILD, which are alternately stacked on top of another.

The substrate 10 may include the first and second cell array regions CAR1 and CAR2 and the connection region CNR. First and second separation structures SS1 and SS2 may be disposed on the first cell array region CAR1 and may be extended in the first direction D1. The first and second separation structures SS1 and SS2 may be disposed spaced apart from each other in the second direction D2. The first separation structures SS1 may be extended to the connection region CNR and the second cell array region CAR2 in the first direction D1. A plurality of first cell regions may be defined between the first and second separation structures SS1 and SS2 which are adjacent to each other or between adjacent ones of the second separation structures SS2. The first vertical channel structures VS1 may be disposed on each of the first cell regions.

The first and third separation structures SS1 and SS3 may be disposed on the second cell array region CAR2 to extend in the first direction D1. The first and third separation structures SS1 and SS3 may be disposed to be adjacent to each other in the second direction D2. A plurality of second cell regions may be defined between the first and third separation structures SS1 and SS3, which are adjacent to each other, or between adjacent ones of the third separation structures SS3. The second vertical channel structures VS2 may be disposed on each of the second cell regions. Each of the first to third separation structures SS1, SS2, and SS3 may be formed of or include an insulating material and may have a single-or multi-layered structure.

The connection region CNR may include first and second outer regions ER1 and ER2, which are adjacent to the first separation structures SS1, and the center region CR, which is disposed between the first and second outer regions ER1 and ER2. The first and second outer regions ER1 and ER2 and the center region CR may be defined between a pair of the first separation structures SS1.

Each of the first and second outer regions ER1 and ER2 may indicate a region which are adjacent to the first separation structures SS1 in the second direction D2. Each of the first and second outer regions ER1 and ER2 may facing the first and second cell region in the first direction D1. The center region CR may indicate a region between the first and second outer regions ER1 and ER2 and may face the first and second cell regions in the first direction D1.

The gate contacts GC may be disposed on the connection region CNR. The gate contacts GC may be provided to penetrate the stack ST at least partially and may be connected to the gate electrodes GE. Since the gate electrodes GE are vertically stacked in the third direction D3, the gate contacts GC, which are respectively connected to different gate electrodes GE, may have different lengths in the third direction D3. In other words, the vertical lengths of the gate contacts GC may be different from each other.

Among the gate electrodes GE, the two gate electrodes located at the topmost level may be referred to as the first and second gate electrodes GE1 and GE2. The first and second gate electrodes GE1 and GE2 may be disposed to be adjacent to each other in the second direction D2. The third and fourth gate contacts GC3 and GC4, which are arranged in the second direction D2, may be provided to penetrate the first and second gate electrodes GE1 and GE2. First to fourth gate contacts GC1 to GC4 may be connected to the first to fourth gate electrodes GE1 to GE4, respectively. The vertical length of each of the third and fourth gate contacts GC3 and GC4 may be larger than the vertical length of each of the first and second gate contacts GC1 and GC2.

The first and second gate contacts GC1 and GC2, which are electrically connected to the first and second gate electrodes GE1 and GE2, may be disposed on the center region CR of the connection region CNR. In particular, the first and second gate contacts GC1 and GC2 may be disposed near the center of the center region CR.

Since the first and second gate electrodes GE1 and GE2 are pierced by other gate contacts GC that are not electrically connected to them, the first and second gate electrodes GE1 and GE2 may have a small sectional area. Thus, each of the first and second gate electrodes GE1 and GE2 may have a larger resistance than other gate electrodes GE therebelow. Accordingly, the transmission speed of signals to the first and second gate electrodes GE1 and GE2 may be slower than that to the other gate electrodes GE, and this signal delay in the first and second gate electrodes GE1 and GE2 may determine the overall operation speed of the memory cell.

As an example, if the first and second gate contacts GC1 and GC2 are disposed on the first or second outer region ER1 or ER2 of the connection region CNR, the distance to the first and second cell regions disposed on an opposite region (i.e., the second or first outer region ER2 or ER1) may be increased. Thus, the transmission speed of signals to the first or second vertical channel structure VS1 or VS2 may further decrease. As a result, the overall operation speed of the memory cell may be reduced.

However, according to some implementations, since the first and second gate contacts GC1 and GC2 are disposed on the center region CR between the first and second outer regions ER1 and ER2, it may be possible to prevent the resistance between the first or second vertical channel structures VS1 and VS2 from being undesirably increased. Accordingly, it may be possible to increase the operation speed of a memory cell and to improve the electrical and reliability characteristics of the semiconductor device.

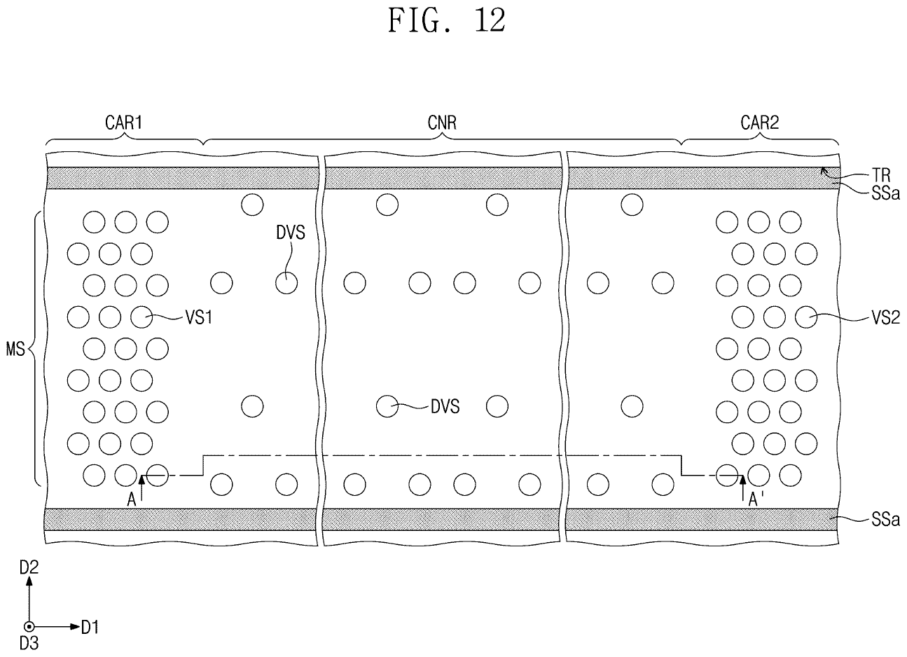

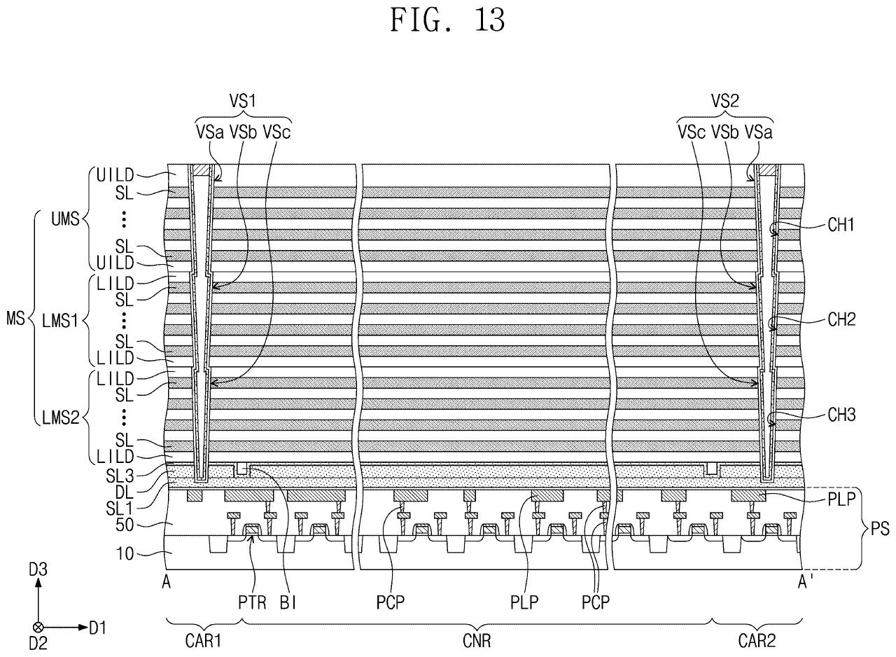

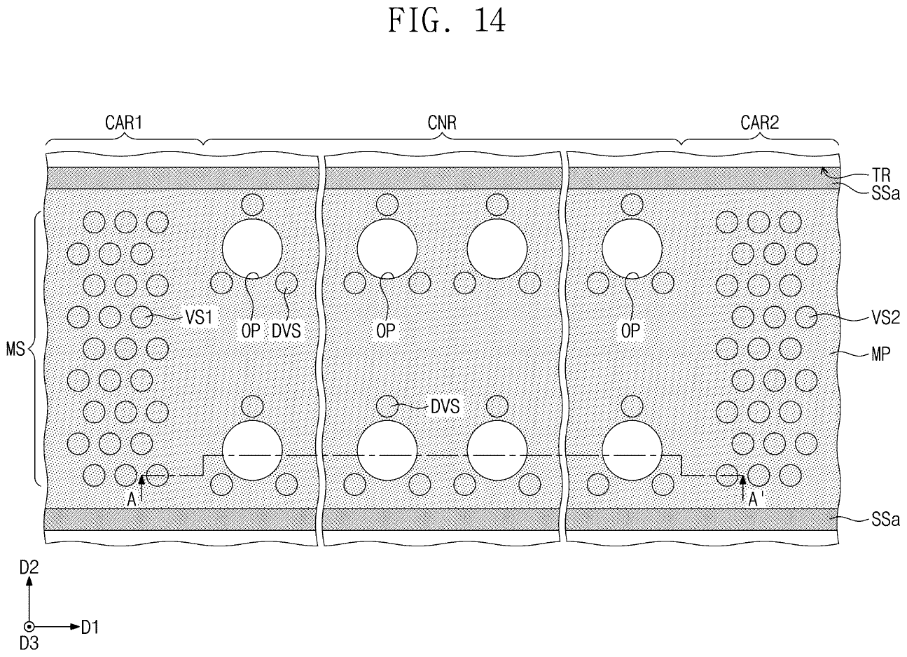

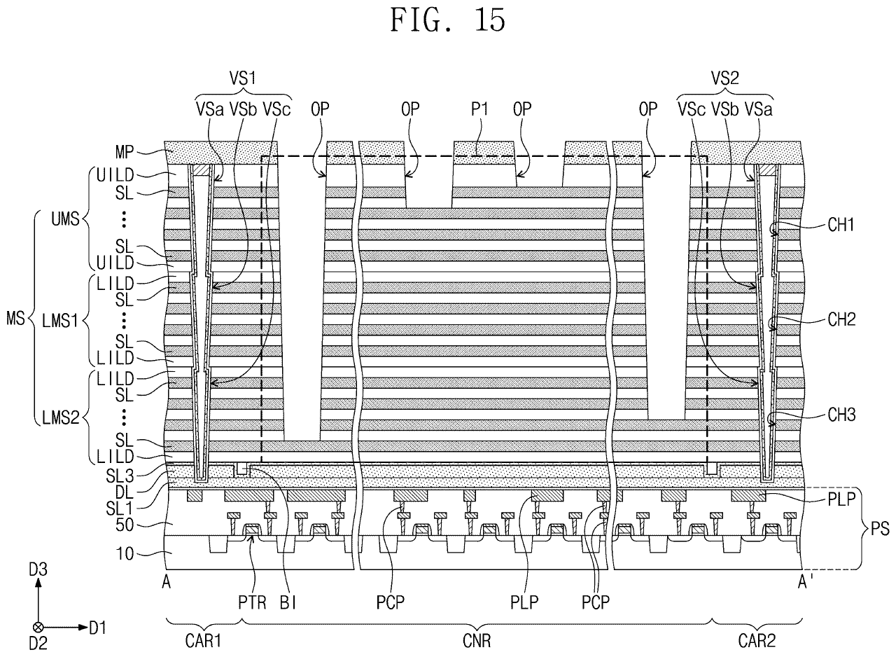

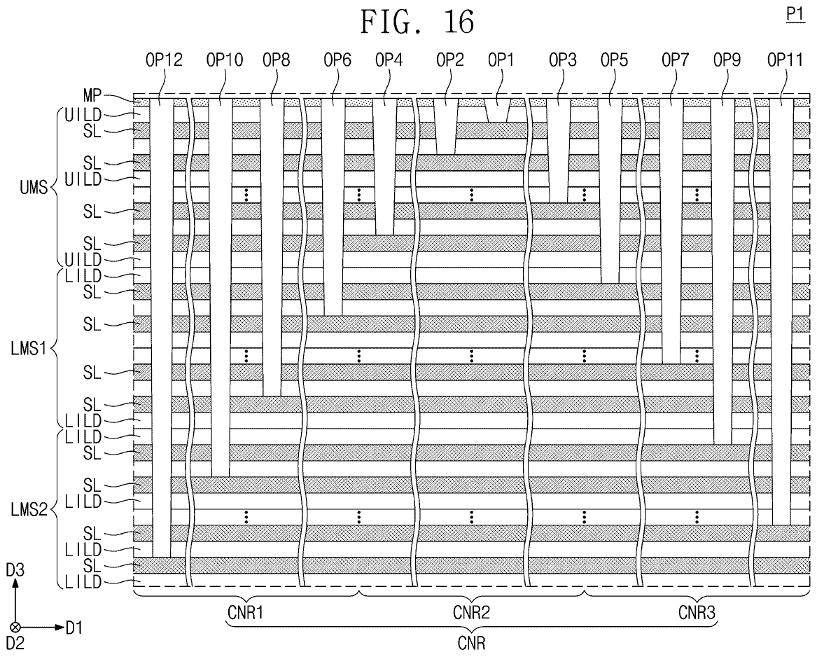

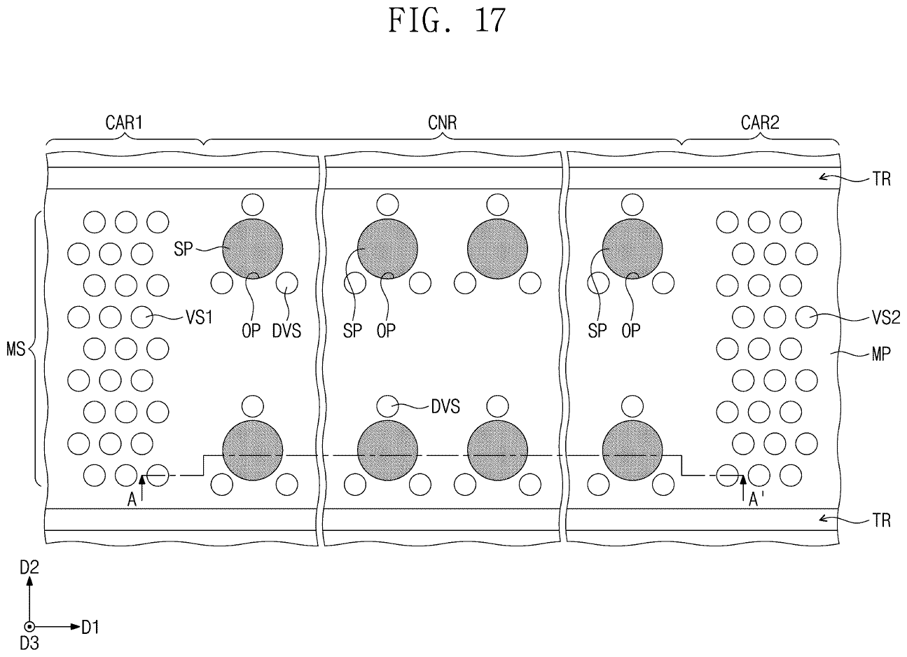

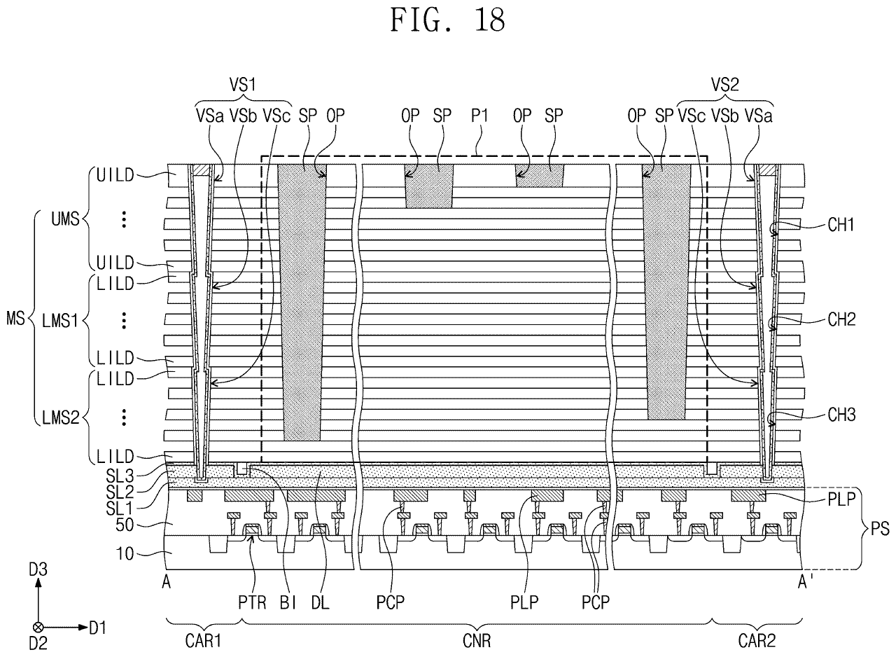

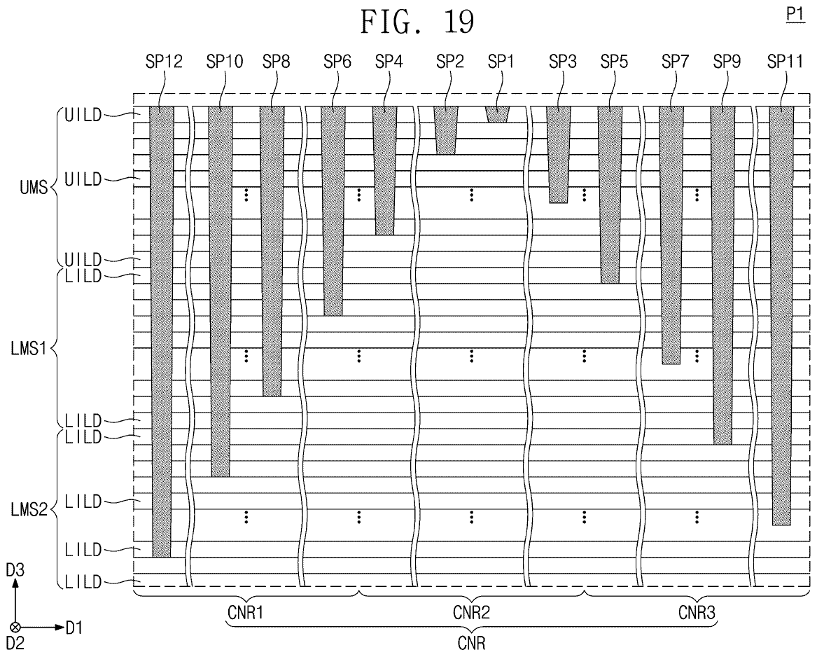

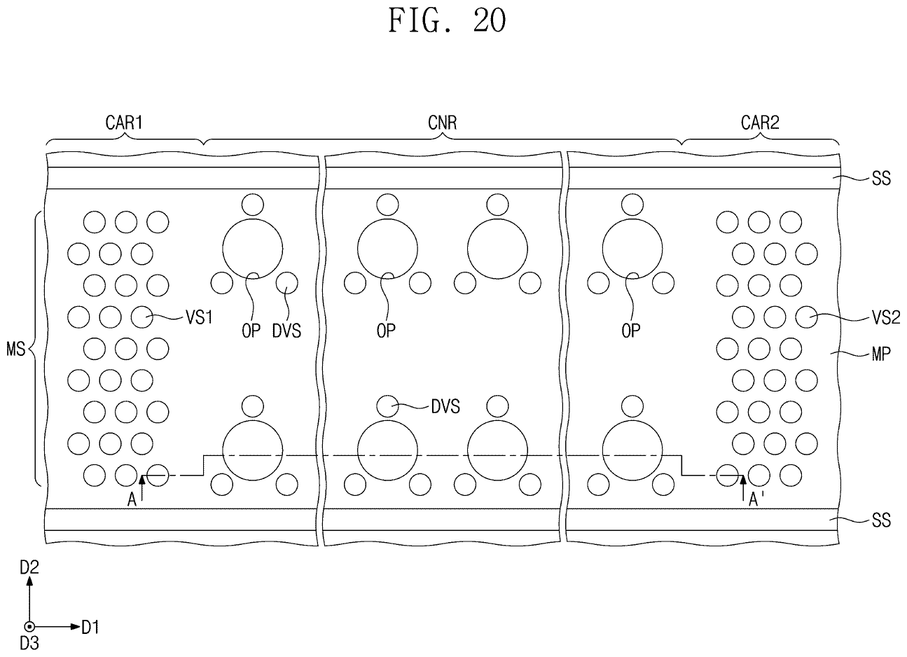

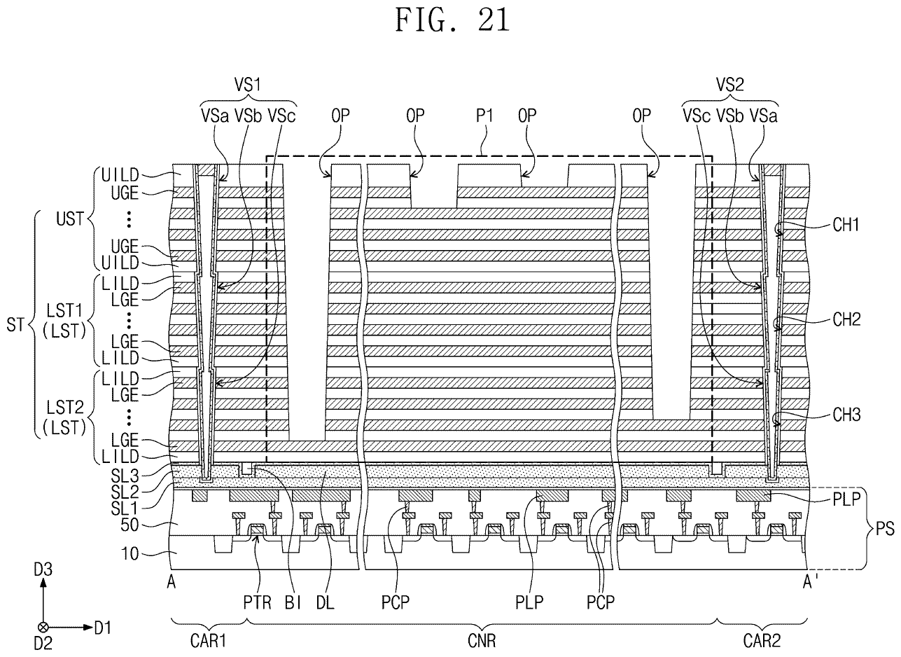

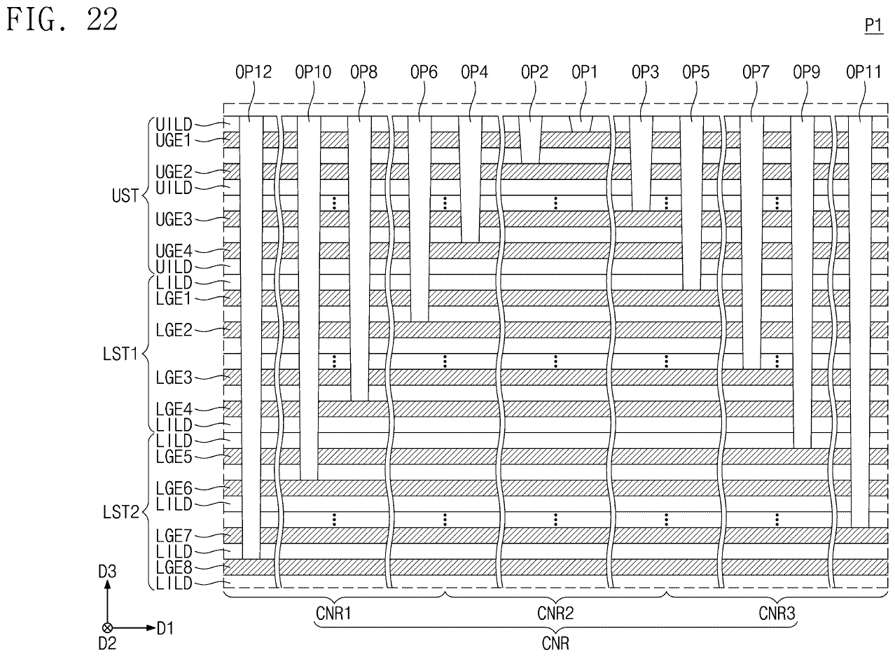

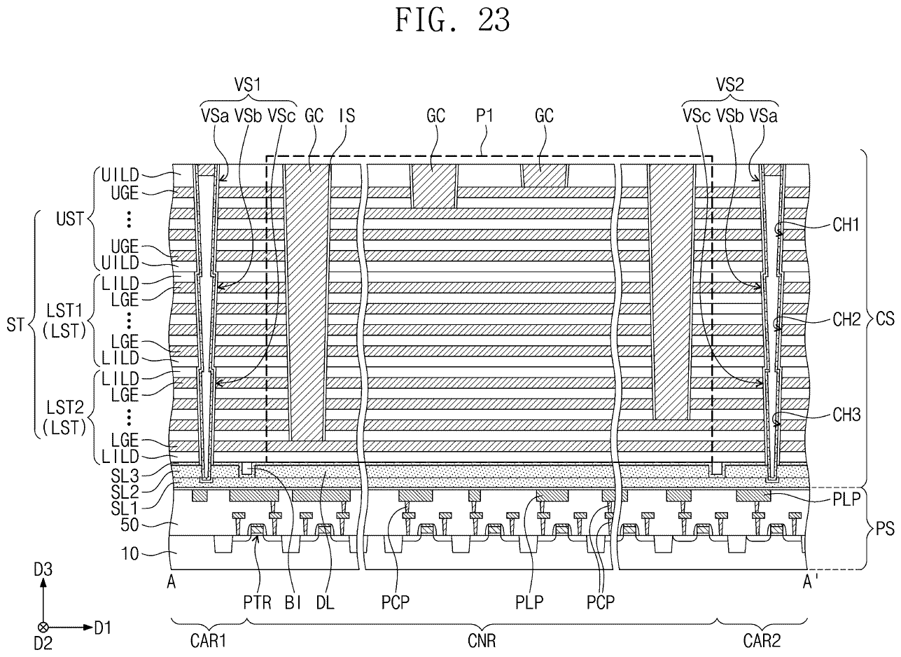

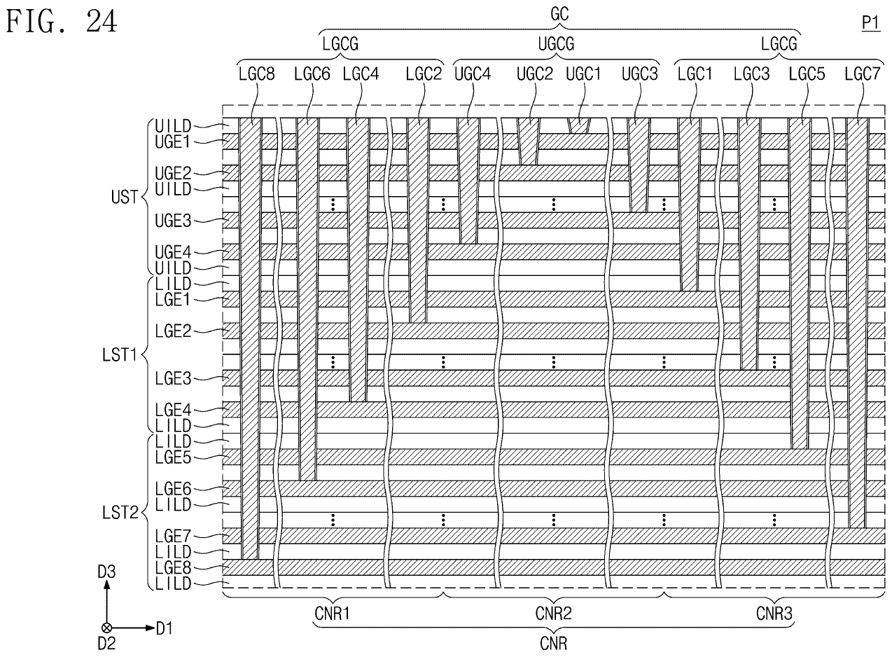

FIGS. 12 to 24 are diagrams illustrating a method of fabricating a semiconductor device, according to some implementations. FIGS. 12, 14, 17, and 20 are plan views illustrating a method of fabricating a semiconductor device, according to some implementations. FIG. 13 is a sectional view taken along a line A-A′ of FIG. 12. FIG. 15 is a sectional view taken along a line A-A′ of FIG. 14. FIG. 16 is an enlarged view illustrating a portion ‘P1’ of FIG. 15. FIG. 18 is a sectional view taken along a line A-A′ of FIG. 17. FIG. 19 is an enlarged view illustrating a portion ‘P1’ of FIG. 18. FIG. 21 is a sectional view taken along a line A-A′ of FIG. 20. FIG. 22 is an enlarged view of a portion ‘P1’ of FIG. 21. FIG. 23 is a sectional view corresponding to FIG. 20. FIG. 24 is an enlarged view illustrating a portion ‘P1’ of FIG. 23.

Referring to FIGS. 12 and 13, the substrate 10 may be provided. The substrate 10 may include the first and second cell array regions CAR1 and CAR2 and the connection region CNR therebetween.

The peripheral circuits PTR may be formed on the substrate 10. The lower insulating layer 50 may be formed on the substrate 10. The peripheral circuit lines PLP and the peripheral contact plugs PCP may be formed in the lower insulating layer 50. The first source layer SL1, the dummy layer DL, and the third source layer SL3 may be sequentially formed on the lower insulating layer 50.

A mold structure MS may be formed on the third source layer SL3. The mold structure MS may have a uniform thickness, on the first and second cell array regions CAR1 and CAR2 and the connection region CNR. An upper mold structure UMS may be disposed on first and second lower mold structures LMS1 and LMS2.

The formation of the mold structure MS may include forming the first and second lower mold structures LMS1 and LMS2 and forming the upper mold structure UMS. The formation of the first lower mold structure LMS1 may include alternately stacking the lower insulating layers LILD and the sacrificial layers SL and performing a patterning process to form the first channel hole CH1. The formation of the second lower mold structure LMS2 may include alternately stacking the lower insulating layers LILD and the sacrificial layers SL and performing a patterning process to form the second channel hole CH2. The formation of the upper mold structure UMS may include alternately stacking the upper insulating layers UILD and the sacrificial layers SL and performing a patterning process to form the third channel hole CH3. The first to third channel holes CH1, CH2, and CH3 may be vertically overlapped with each other and may be formed on the first and second cell array regions CAR1 and CAR2. When viewed in a plan view, the first to third channel holes CH1, CH2, and CH3 may have a circular shape or an elliptical shape (e.g., having a longitudinal axis parallel to the first or second direction D1 or D2). In the present specification, the sacrificial layers SL in the upper mold structure UMS may be referred to as an upper sacrificial layer, and the sacrificial layers SL in the first and second lower mold structures LMS1 and LMS2 may be referred to as first and second lower sacrificial layers, respectively.

The first and second vertical channel structures VS1 and VS2 may be formed in the first to third channel holes CH1, CH2, and CH3. The formation of the first and second vertical channel structures VS1 and VS2 may include sequentially depositing a data storing layer and a vertical channel layer in vertical channel holes and etching and planarizing the data storing layer and the vertical channel layer. Thus, the vertical channel structures VS, each of which includes the data storage pattern DSP, the vertical semiconductor pattern VP, and the gapfill insulating pattern VI of FIG. 7B, may be formed.

On the connection region CNR, the dummy vertical structures DVS may be formed in vertical dummy holes penetrating the mold structure MS. The formation of the vertical dummy holes may be substantially the same as the formation of the vertical channel holes. In some examples, the vertical dummy holes and the vertical channel holes may be formed at the same time. The formation of the dummy vertical structures DVS may include filling the vertical dummy holes with an insulating material and planarizing the insulating material.

Trenches TR may be formed on the first and second cell array regions CAR1 and CAR2 and the connection region CNR to penetrate the mold structure MS. The formation of the trenches TR may include forming a mask pattern on the mold structure MS and removing a portion of the mold structure MS through an anisotropic etching process using the mask pattern. The trenches TR may be extended in the first direction D1 and may be spaced apart from each other in the second direction D2.

The preliminary separation structures SSa may be formed in the trenches TR. The preliminary separation structures SSa may include a material having an etch selectivity with respect to the upper and lower insulating layers UILD and LILD and the sacrificial layers SL. For example, the preliminary separation structures SSa may be formed of or include poly silicon.

Referring to FIGS. 14 to 16, contact holes OP may be formed on the connection region CNR to penetrate a portion of the mold structure MS. The formation of the contact holes OP may include forming a mask pattern MP and performing an etching process using the mask pattern MP to remove a portion of the mold structure MS. In some implementations, the mask pattern MP may be formed on the mold structure MS to expose the contact holes OP and cover the dummy vertical structures DVS.

The contact holes OP may be formed to expose the sacrificial layers SL at different level In other words, the contact holes OP may have different vertical depths from each other, and the vertical depths of the contact holes OP may be determined by the position of the mask pattern MP and the number of etching processes performed thereon. The contact holes OP may be formed on the second connection region CNR2 to have a relatively short vertical length. For example, contact holes OP5 to OP12 on the first and third connection regions CNR1 and CNR3 may be formed to have a relatively large vertical length, compared with contact holes OP1 to OP4 on the second connection region CNR2. The contact holes OP1 to OP4 formed on the second connection regions CNR2 may be formed to expose the sacrificial layers SL of the upper mold structure UMS. The contact holes OP5 to OP12 formed on the first and third connection regions CNR1 and CNR3 may be formed to expose the sacrificial layers SL of the first and second lower mold structures LMS1 and LMS2.

Referring to FIGS. 17 to 19, sacrificial patterns SP may be formed on the contact holes. The formation of the sacrificial patterns SP may include filling the contact holes OP with a sacrificial material and performing a planarization process on the sacrificial material. Thus, top surfaces of the sacrificial patterns SP may be coplanar with the top surface of the uppermost one of the upper insulating layers UILD. The sacrificial patterns SP may include a material having an etch selectivity. For example, the sacrificial patterns SP may be formed of or include silicon nitride. The sacrificial patterns SP may include sacrificial patterns SP1 to SP12, which are provided to penetrate at least portion of the upper insulating layers UILD and/or the lower insulating layers LILD. The sacrificial patterns SP1 to SP12 may have different vertical lengths from each other.

Thereafter, the preliminary separation structures SSa may be removed. Thus, the trenches TR may be exposed to the outside again. The selective removal of the preliminary separation structures SSa may be performed using an etching process using an etchant containing hydrofluoric acid.

The dummy layer DL may be removed from the first and second cell array regions CAR1 and CAR2. The data storage patterns DSP of FIG. 7B of the first and second vertical channel structures VS1 and VS2, which are exposed by the removal of the dummy layer DL, may be partially removed. Thereafter, the second source layer SL2 may be formed.

The sacrificial layers SL exposed by the trenches TR may be selectively removed after the removal of the preliminary separation structures SSa. In some implementations, a wet etching process using etching solution with an etch selectivity may be used to remove the sacrificial layers SL.

Due to the selective removal of the sacrificial layers SL, the mold structure MS may be structurally weakened. Accordingly, the mold structure MS may collapse or tilt. In this case, since the vertical channel structures VS, the dummy vertical structures DVS, and the sacrificial patterns SP support the mold structure MS, the mold structure MS may be supported during a subsequent process of forming the gate electrodes GE.

Referring to FIGS. 20 to 22, the upper and lower gate electrodes UGE and LGE may be formed in a space, from which the sacrificial layers SL of FIG. 18 is removed. The upper and lower gate electrodes UGE and LGE may fully or partially fill a space, from which the sacrificial layers SL is removed. For example, the formation of the upper and lower gate electrodes UGE and LGE may include sequentially depositing a metal nitride layer (e.g., TiN, TaN, or WN) and a metal layer (e.g., W, Al, Ti, Ta, Co, or Cu). Thus, the stack ST may be formed on the substrate 10.

After the formation of the stack ST, the separation structures SS may be formed in the trenches TR. The formation of the separation structures SS may include filling the trenches TR with an insulating material and performing a planarization process on the insulating material to expose the top surface of the uppermost one of the insulating layers ILD. The separation structures SS may be formed by a chemical vapor deposition process and/or an atomic layer deposition process, and due to a high aspect ratio of the trenches TR, a void may be formed in the separation structures SS. For example, the separation structures SS may be formed of or include at least one of silicon oxide, silicon nitride, silicon oxynitride, or low-k dielectric materials.

The sacrificial patterns SP1 to SP12 of FIG. 19 may be removed. The removal of the sacrificial patterns SP1 to SP12 may be performed through a wet etching process using etching solution with an etch selectivity. Since the sacrificial patterns SP1 to SP12 of FIG. 19 are removed, contact holes OP1 to OP12 may be exposed. Thus, top surfaces of the upper and lower gate electrodes UGE and LGE may be partially exposed.

Referring to FIGS. 23 and 24, the gate contacts GC may be formed in the contact holes OP. In some implementations, the formation of each of the gate contacts GC may include conformally forming the insulating pattern IS in the contact hole OP, performing an etch-back process to partially expose top surfaces of the upper or lower gate electrodes UGE and LGE, and forming a conductive material to fill the contact hole OP. Thereafter, a planarization process may be performed on the gate contacts GC. Thus, the gate contacts GC may have top surfaces that are coplanar with a top surface of the uppermost one of the upper insulating layers UILD.

The gate contacts GC may be in contact with the exposed top surfaces of the upper or lower gate electrodes UGE and LGE. Each of the gate contacts GC may be electrically and physically connected to one of the upper or lower gate electrodes UGE and LGE. The gate contacts GC on the second connection region CNR2 may be referred to as the upper gate contacts UGCG and may be electrically and physically connected to the upper gate electrodes UGE. The gate contacts GC on the first and third connection regions CNR1 and CNR3 may be referred to as the lower gate contacts LGCG and may be electrically and physically connected to the lower gate electrodes LGE.

Referring back to FIGS. 5 and 6, the first interlayer insulating layer 150 may be formed on the stack ST. The first interlayer insulating layer 150 may cover the stack ST, the first and second vertical channel structures VS1 and VS2, the dummy vertical structures DVS and the gate contacts GC with a uniform thickness.

The bit line contact plugs BLCP may be formed on a cell array region CAR to penetrate the first interlayer insulating layer 150 and to be connected to vertical channel structures VS. Connection contact plugs CLCP may be formed on the connection region CNR to penetrate the first interlayer insulating layer 150 and to be connected to the gate contacts GC. In some examples, the bit line contact plugs BLCP and the connection contact plugs CLCP may be formed through the same process.

In the first and second cell array regions CAR1 and CAR2, the bit lines BL may be formed on the first interlayer insulating layer 150. Each of the bit lines BL may be connected to a corresponding one of the bit line contact plugs BLCP. In the connection region CNR, the connection lines CL may be formed on the first interlayer insulating layer 150. Each of the connection lines CL may be connected to a corresponding one of the connection contact plugs CLCP. In some examples, the bit lines BL and the connection lines CL may be formed through the same process.

According to some implementations, a semiconductor device may include gate contacts disposed on connection regions that are placed between first and second cell array regions spaced apart from each other in a first direction. The gate contacts may be connected to gate electrodes of a stack and may be used to supply voltages to first and second vertical channel structures disposed on the first and second cell array regions, respectively, through the gate electrodes. In some implementations, the gate contacts, which are connected to the gate electrodes with high resistance, may be disposed in a center region of the connection region, when viewed in a plan view. In this case, the resistance between the gate contacts, which are connected to the gate electrodes with high resistance, and the first or second vertical channel structures may be prevented from increasing beyond a desired range. Accordingly, it may be possible to increase the operation speed of a memory cell and to improve the electrical and reliability characteristics of the semiconductor device.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While example implementations have been particularly shown and described, it will be understood by one of ordinary skill in the art that variations in form and detail may be made therein without departing from the spirit and scope of the attached claims.

What is claimed is:

1. A semiconductor device, comprising:
a substrate comprising a first cell array region, a first connection region, a second connection region, a third connection region, and a second cell array region that are sequentially arranged in a first direction;
a lower stack comprising a plurality of lower insulating layers and a plurality of lower gate electrodes on the substrate, wherein each of the plurality of lower insulating layers and each of the plurality of lower gate electrodes are alternately stacked on top of one each;
an upper stack comprising a plurality of upper insulating layers and a plurality of upper gate electrodes on the lower stack, wherein each of the plurality of upper insulating layers and each of the plurality of upper gate electrodes are alternately stacked on top of one each;
a first vertical channel structure at the first cell array region, the first vertical channel structure extending into the lower stack and the upper stack;
a second vertical channel structure at the second cell array region, the second vertical channel structure extending into the lower stack and the upper stack; and
a plurality of gate contacts at the first connection region, the second connection region, and the third connection region, and arranged in the first direction,
wherein the plurality of gate contacts comprise:
a plurality of upper gate contacts extending into at least a portion of the upper stack and connected to the plurality of upper gate electrodes, the plurality of upper gate contacts being at the second connection region, and
a plurality of lower gate contacts extending into at least a portion of the lower stack and connected to the plurality of lower gate electrodes, the plurality of lower gate contacts being at the first connection region and the third connection region.

2. The semiconductor device of claim 1, wherein the plurality of upper gate contacts comprise a first upper gate contact that is connected to a first upper gate electrode, the first upper gate electrode being an upper most gate electrode of the plurality of upper gate electrodes, and
wherein the plurality of lower gate contacts extend into the first upper gate electrode.

3. The semiconductor device of claim 2, wherein the plurality of upper gate contacts comprise a second upper gate contact and a third upper gate contact,
wherein the first upper gate contact is interposed between the second upper gate contact and the third upper gate contact, and
wherein a vertical length of the first upper gate contact is less than (i) a vertical length of the second upper gate contact and (ii) a vertical length of the third upper gate contact.

4. The semiconductor device of claim 3, wherein a vertical length of each of the lower gate contacts is greater than (i) the vertical length of the second upper gate contact and (ii) the vertical length of the third upper gate contact.

5. The semiconductor device of claim 1, wherein the upper gate contacts comprise a first upper gate contact, a second upper gate contact, and a third upper gate contact that are sequentially arranged in the first direction,
wherein a vertical length of the first upper gate contact is less than a vertical length of the second upper gate contact, and
wherein the vertical length of the second upper gate contact is less than a vertical length of the third upper gate contact.

6. The semiconductor device of claim 1, wherein a vertical length of each of the first vertical channel structure and the second vertical channel structure is greater than a vertical length of each of the plurality of gate contacts.

7. The semiconductor device of claim 1, wherein each of the first vertical channel structure and the second vertical channel structure comprises:
a gapfill insulating pattern;
a vertical semiconductor pattern surrounding side and top surfaces of the gapfill insulating pattern; and
a data storage pattern surrounding a side surface of the vertical semiconductor pattern.

8. The semiconductor device of claim 1, wherein each of the first vertical channel structure and the second vertical channel structure comprises (i) a first portion that extends into the upper stack, and (ii) a second portion that is connected to the first portion and that extends into the lower stack, and
wherein a width of each of the first portion and the second portion is greatest at a respective upper end of the first portion and the second portion.

9. The semiconductor device of claim 8, wherein a width of the first portion at a lower end of the first portion is less than a maximum width of the second portion.

10. The semiconductor device of claim 1, comprising:
a plurality of connection lines on the plurality of gate contacts, respectively, and connected to the plurality of gate contacts, respectively; and
a plurality of bit lines on the first vertical channel structure and the second vertical channel structure, the plurality of bit lines being connected to the first vertical channel structure and the second vertical channel structure.

11. The semiconductor device of claim 1, wherein a length of the lower stack in the first direction is equal to a length of the upper stack in the first direction.

12. A semiconductor device, comprising:
a substrate including a first cell array region, a first connection region, a second connection region, a third connection region, and a second cell array region that are sequentially arranged in a first direction;
a first stack, a second stack, and a third stack that are sequentially disposed on the substrate, wherein each of the first stack, the second stack, and the third stack includes a plurality of insulating layers and a plurality of gate electrodes, wherein each of the plurality of insulating layers and each of the plurality of gate electrodes are alternately stacked on top of one each;
a first vertical channel structure at the first cell array region, the first vertical channel structure extending into the first stack, the second stack, and the third stack;
a second vertical channel structure at the second cell array region, the second vertical channel structure extending into the first stack, the second stack, and the third stack; and
a plurality of gate contacts that are sequentially arranged, in the first direction, at a first connection region, a second connection region, and a third connection region.
wherein the gate contacts comprise:
a plurality of first outer gate contacts that extend into at least a portion of the second stack and that are connected to the plurality of gate electrodes of the second stack, the plurality of first outer gate contacts being at the first connection region,
a plurality of inner gate contacts that extend into at least a portion of the first stack and that are connected to the plurality of gate electrodes of the first stack, the plurality of inner gate contacts being at the second connection region, and
a plurality of second outer gate contacts that extend into at least a portion of the third stack and that are connected to the plurality of gate electrodes of the third stack, the plurality of second outer gate contacts being at the third connection region.

13. The semiconductor device of claim 12, wherein each of the first and second vertical channel structures comprises:
a first portion penetrating the first stack;
a second portion penetrating the second stack; and
a third portion penetrating the third stack,
wherein a width of each of the first portion, the second portion, and the third portion is greatest at a respective lower end of the first portion, the second portion, and the third portion.

14. The semiconductor device of claim 12, wherein a vertical length of each of the plurality of inner gate contacts is less than a vertical length of each of the plurality of first outer gate contacts and each of the plurality of second outer gate contacts.

15. The semiconductor device of claim 12, wherein bottom surfaces of the plurality of inner gate contacts, the plurality of first outer gate contacts, and the plurality of second outer gate contacts are coplanar.

16. The semiconductor device of claim 12, comprising:
a plurality of peripheral circuits integrated on the substrate;
a plurality of first bonding pads connected to the peripheral circuits; and
second bonding pads connected to the first and second vertical channel structures,
wherein the first bonding pads are bonded to the second bonding pads.

17. The semiconductor device of claim 12, wherein the first stack, the second stack, and the third stack have a same length in the first direction.

18. The semiconductor device of claim 12, wherein a vertical length of each of the first and second vertical channel structures is larger than a vertical length of each of the gate contacts.

19. An electronic system, comprising:
a main substrate;
a semiconductor device on the main substrate; and
a controller on the main substrate and connected to the semiconductor device,
wherein the semiconductor device comprises:
a substrate comprising a first cell array region, a first connection region, a second connection region, a third connection region, and a second cell array region that are sequentially arranged in a first direction,
a lower stack comprising a plurality of lower insulating layers and a plurality of lower gate electrodes, on the substrate, wherein each of the plurality of lower insulating layers and each of the plurality of lower gate electrodes are alternately stacked on top of one each,
an upper stack comprising a plurality of upper insulating layers and a plurality of upper gate electrodes, on the lower stack, wherein each of the plurality of upper insulating layers and each of the plurality of upper gate electrodes are alternately stacked on top of one each,
a first vertical channel structure on the first cell array region, the first vertical channel structure extending into the lower stack and the upper stack,
a second vertical channel structure on the second cell array region, the second vertical channel structure extending into the lower stack and the upper stack, and
a plurality of gate contacts at the first connection region, the second connection region, and the third connection region, and arranged in the first direction,
wherein the plurality of gate contacts comprise:
a plurality of upper gate contacts extending into at least a portion of the upper stack and connected to the plurality of upper gate electrodes, the plurality of gate contacts being at the second connection region, and
a plurality of lower gate contacts extending into at least a portion of the lower stack and connected to the plurality of lower gate electrodes, the plurality of lower gate contacts being at the first connection region and the third connection region.

20. The electronic system of claim 19, wherein a vertical length of each of the plurality of upper gate contacts is less than a vertical length of each of the plurality of lower gate contacts, and
wherein the plurality of upper gate contacts comprise a first upper gate contact connected to an uppermost upper gate electrode of the plurality of upper gate electrodes.
